(19) United States
(12) Patent Application Publication
(10) Pub. No.: US 2025/0126948 A1
(43) Pub. Date: Apr. 17, 2025

(54) Display Device

(71) Applicant: LG Display Co., Ltd., Seoul (KR)

(72) Inventors: TaeYong Kim, Anyang-si (KR); MinSeok Kim, Seoul (KR); HyunGon Kim, Seoul (KR); Soyi Lee, Paju-si (KR)

(21) Appl. No.: 18/784,615

(22) Filed: Jul. 25, 2024

(30) Foreign Application Priority Data
Oct. 13, 2023 (KR) 10-2023-0136745

(51) Int. Cl. H01L 27/15; G09G 3/3233

(52) U.S. Cl. CPC H10H 29/142; G09G 3/3233; G09G 2300/0819; G09G 2300/0852; G09G 2320/0233; G09G 2330/08

(57) ABSTRACT

A display device presented herein includes: a substrate having a plurality of pixel areas; a plurality of pixels in the plurality of pixel areas, each of the plurality of pixels including a first sub-pixel, a second sub-pixel, a third sub-pixel, and a reserve sub-pixel; a first plurality of light-emitting elements in the first sub-pixel and the reserve sub-pixel; a second plurality of light-emitting elements in the second sub-pixel and the reserve sub-pixel; and a third plurality of light-emitting elements in the third sub-pixel and the reserve sub-pixel; in which a first light-emitting element of the first plurality of light-emitting elements, a second light-emitting element of the second plurality of light-emitting elements, and a third light-emitting element of the third plurality of light-emitting elements are on different layers in the reserve sub-pixel.

### CROSS-REFERENCE TO RELATED APPLICATION

This application claims the priority from Republic of Korea Patent Application No. 10-2023-0136745 filed on Oct. 13, 2023, which is hereby incorporated by reference in its entirety.

### BACKGROUND

### Technical Field

The present disclosure relates to a display device, and more particularly, to a display device using a light-emitting diode (LED).

### Description of Related Art

As display devices used for a monitor of a computer, a TV set, a mobile phone, and the like, there are an organic light-emitting display (OLED) configured to autonomously emit, and a liquid crystal display (LCD) that requires a separate light source.

The range of application of the display devices is diversified from the monitor of the computer and the TV set to personal mobile devices, and studies are being conducted on the display devices having wide display areas and having reduced volumes and weights.

In addition, recently, a display device including a light-emitting diode (LED) which may be made of inorganic materials has attracted attention as a next-generation display device. Because the LED is made of an inorganic material instead of an organic material, the LED is more reliable and has a longer lifespan than a liquid crystal display device or an organic light-emitting display device. In addition, the LED may be quickly turned on or off, have excellent luminous efficiency, high impact resistance, and great stability, and display high-brightness images.

The description provided in the background section should not be assumed to be prior art merely because it is mentioned in or associated with the background section. The background section may include information that describes one or more embodiments of the subject technology.

### SUMMARY

An embodiment of the present disclosure is to provide a transparent display device having an improved transmittance rate.

Another embodiment of the present disclosure is to provide a display device including a reserve sub-pixel to repair a defective light-emitting element.

Still another embodiment of the present disclosure is to repair a plurality of sub-pixels by using a single reserve sub-pixel.

Yet another embodiment of the present disclosure is to provide a display device in which a plurality of light-emitting elements disposed in a reserve sub-pixel is vertically stacked to reduce an area of the reserve sub-pixel.

Still yet another embodiment of the present disclosure is to provide a display device in which an area of a reserve sub-pixel is reduced to maximize or at least increase an area of a transmissive area.

A further embodiment of the present disclosure is to provide a display device in which a high-density drive current is supplied to a light-emitting element to improve luminous efficiency of the light-emitting element.

Another further embodiment of the present disclosure is to provide a display device capable of displaying a high-resolution image.

Embodiments of the present disclosure are not limited to the above-mentioned embodiments, and other embodiments, which are not mentioned above, can be clearly understood by those skilled in the art from the following descriptions.

To achieve these and other embodiments of the inventive concepts, as embodied and broadly described herein, a display device includes: a substrate having a plurality of pixel areas; a plurality of pixels in the plurality of pixel areas, each of the plurality of pixels including a first sub-pixel, a second sub-pixel, a third sub-pixel, and a reserve sub-pixel; a first plurality of light-emitting elements in the first sub-pixel and the reserve sub-pixel; a second plurality of light-emitting elements in the second sub-pixel and the reserve sub-pixel; and a third plurality of light-emitting elements in the third sub-pixel and the reserve sub-pixel; in which a first light-emitting element of the first plurality of light-emitting elements, a second light-emitting element of the second plurality of light-emitting elements, and a third light-emitting element of the third plurality of light-emitting elements are on different layers in the reserve sub-pixel. Therefore, the first light-emitting element, the second light-emitting element and the third light-emitting element in the reserve sub-pixel are vertically stacked, which may reduce the area of the reserve sub-pixel.

Other detailed matters of the embodiments of the present disclosure are included in the detailed description and the drawings.

According to the present disclosure, it is possible to implement the transparent display device with the improved transmittance rate.

According to the present disclosure, the opaque components may overlap one another, among the components of the display device, thereby ensuring the maximum or at least increased area of the transmissive area of the display device.

According to the present disclosure, it is possible to repair the plurality of sub-pixels by using the reserve sub-pixel.

According to the present disclosure, it is possible to repair the plurality of sub-pixels by using one reserve sub-pixel.

According to the present disclosure, the first light-emitting element, the second light-emitting element and the third light-emitting element in the reserve sub-pixel are vertically stacked, which may reduce the area of the reserve sub-pixel.

According to the present disclosure, it is possible to maximize or at least increase the area of the transmissive area by reducing the area of the reserve sub-pixel.

According to the present disclosure, it is possible to improve the luminous efficiency of the light-emitting element by supplying the high-density drive current to the light-emitting element.

According to the present disclosure, it is possible to implement the high-resolution display device.

The effects according to the present disclosure are not limited to the contents exemplified above, and more various effects are included in the present disclosure.

It is to be understood that both the foregoing general description and the following detailed description are exemplary and explanatory and are intended to provide further explanation of the inventive concepts as claimed.

### BRIEF DESCRIPTION OF DRAWINGS

The accompanying drawings, that may be included to provide a further understanding of the disclosure and may be incorporated in and constitute a part of the disclosure, illustrate embodiments of the disclosure and together with the description serve to explain various principles of the disclosure.

The above and other embodiments, features and other advantages of the present disclosure will be more clearly understood from the following detailed description taken in conjunction with the accompanying drawings, in which:

FIG. 1 is a schematic configuration view of a display device according to one or more embodiments of the present disclosure;

FIG. 2A is a partial cross-sectional view of the display device according to one or more embodiments of the present disclosure;

FIG. 2B is a perspective view of a tiling display device according to one or more embodiments of the present disclosure;

FIG. 3A is a schematic enlarged top plan view of a display area of the display device according to one or more embodiments of the present disclosure;

FIG. 3B is a schematic configuration view of a pixel of the display device according to one or more embodiments of the present disclosure;

FIG. 4 is an enlarged top plan view of the display area of the display device according to one or more embodiments of the present disclosure;

FIGS. 5 to 7 are cross-sectional views of a plurality of sub-pixels of the display device according to one or more embodiments of the present disclosure;

FIG. 8 is a cross-sectional view of a reserve sub-pixel of the display device according to one or more embodiments of the present disclosure; and

FIGS. 9 and 10 are cross-sectional views of a welding area of the display device according to one or more embodiments of the present disclosure.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

Reference will now be made in detail to embodiments of the present disclosure, examples of which may be illustrated in the accompanying drawings. In the following description, when a detailed description of well-known functions or configurations related to this document is determined to unnecessarily cloud a gist of the inventive concept, the detailed description thereof will be omitted or briefly provided. The progression of processing steps and/or operations described is an example; however, the sequence of steps and/or operations is not limited to that set forth herein and may be changed as is known in the art, with the exception of steps and/or operations necessarily occurring in a particular order. Like reference numerals designate like elements throughout. Names of the respective elements used in the following explanations may be selected only for convenience of writing the specification and may be thus different from those used in actual products.

Advantages and characteristics of the present disclosure and a method of achieving the advantages and characteristics will be clear by referring to embodiments described below in detail together with the accompanying drawings. However, the present disclosure is not limited to the embodiments disclosed herein but will be implemented in various forms. The embodiments are provided by way of example only so that those skilled in the art can fully understand the disclosures of the present disclosure and the scope of the present disclosure.

The shapes, sizes, areas, ratios, angles, numbers, and the like illustrated in the accompanying drawings for describing the embodiments of the present disclosure are merely examples, and the present disclosure is not limited thereto. Like reference numerals generally denote like elements throughout the disclosure. Further, in the following description of the present disclosure, a detailed explanation of known related technologies may be omitted or briefly provided to avoid unnecessarily obscuring the subject matter of the present disclosure. The terms such as “including,” “having,” and “comprising” used herein are generally intended to allow other components to be added unless the terms are used with the term “only”. Any references to singular may include plural unless expressly stated otherwise.

Components are interpreted to include an ordinary error range even if not expressly stated

Where positional relationships are described, for example, where the positional relationship between two parts is described using “on,” “over,” “under,” “above,” “below,” “beneath,” “near,” “close to,” or “adjacent to,” “beside,” “next to,” or the like, one or more other parts may be disposed between the two parts unless a more limiting term, such as “immediate(ly),” “direct(ly),” or “close(ly)” is used. For example, when a structure is described as being positioned “on,” “over,” “under,” “above,” “below,” “beneath,” “near,” “close to,” or “adjacent to,” “beside,” or “next to” another structure, this description should be construed as including a case in which the structures contact each other as well as a case in which a third structure is disposed or interposed therebetween. Furthermore, the terms “left,” “right,” “top,” “bottom,” “downward,” “upward,” “upper,” “lower,” and the like refer to an arbitrary frame of reference.

When an element or layer is disposed “on” another element or layer, another layer or another element may be interposed directly on the other element or therebetween.

Although the terms “first”, “second”, “A,” “B,” “(a),” “(b)” and the like are used for describing various components, these components are not confined by these terms. These terms are merely used for distinguishing one component from the other components. Therefore, a first component to be mentioned below may be a second component in a technical concept of the present disclosure. Also, when an element or layer is described as being “connected,” “coupled,” or “adhered” to another element or layer, the element or layer can not only be directly connected, or adhered to that other element or layer, but also be indirectly connected, or adhered to that other another element or layer with one or more intervening elements or layers “disposed” between the elements or layers, unless otherwise specified.

Like reference numerals generally denote like elements throughout the disclosure.

A size and a thickness of each component illustrated in the drawing are illustrated for convenience of description, and the present disclosure is not limited to the size and the thickness of the component illustrated.

The term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, or the third element.

The features of various embodiments of the present disclosure can be partially or entirely adhered to or combined with each other and can be interlocked and operated in technically various ways, and the embodiments can be carried out independently of or in association with each other.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

A transistor used in a display device according to embodiments of the present disclosure may be implemented as any one transistor of an n-channel transistor (NMOS) and a p-channel transistor (PMOS). The transistor may be implemented as an oxide semiconductor transistor having an oxide semiconductor as an active layer or a low temperature poly-silicon (LTPS) transistor having LTPS as the active layer. The transistor may at least include a gate electrode, a source electrode, and a drain electrode. The transistor may be implemented as a thin film transistor (TFT) on a display panel. A carrier in the transistor flows from a source electrode to a drain electrode. In the case of the n-channel transistor (NMOS), since the carrier is an electron, a source voltage may be lower than a drain voltage so that the electron may flow from the source electrode to the drain electrode. In the n-channel transistor (NMOS), a current may flow from the drain electrode to the source electrode, and the source electrode may be an output terminal. In the case of the p-channel transistor (PMOS), since the carrier is a hole, the source voltage may be higher than the drain voltage so that the hole may flow from the source electrode to the drain electrode. Since the hole flows from the source electrode to the drain electrode in the p-channel transistor (PMOS), the current may flow from a source electrode to a drain electrode, and the drain electrode may be the output terminal. Accordingly, it should be noted that since the source and the drain may be changed according to an applied voltage, the source and the drain of the transistor are not fixed. In the present disclosure, a description is made by assuming that the transistor is the n-channel transistor (NMOS), but the present disclosure is not limited thereto, but the p-channel transistor may be used, and as a result, a circuit configuration may also be changed.

A gate signal of the transistor used as switch elements may swing between a gate on voltage and a gate off voltage. The gate on voltage may be set to a voltage higher than a threshold voltage Vth of the transistor, and the gate off voltage may be set to a voltage lower than the threshold voltage Vth of the transistor. The transistor is turned on in response to the gate on voltage, while turned off in response to the gate off voltage. In the case of the n-channel transistor (NMOS), the gate on voltage may be a gate high voltage (VGH), and the gate off voltage may be a gate low voltage (VGL). In the case of the p-channel transistor (PMOS), the gate on voltage may be the gate low voltage (VGL), and the gate off voltage may be the gate high voltage (VGH).

Hereinafter, embodiments of the present disclosure will be described in detail with reference to accompanying drawings.

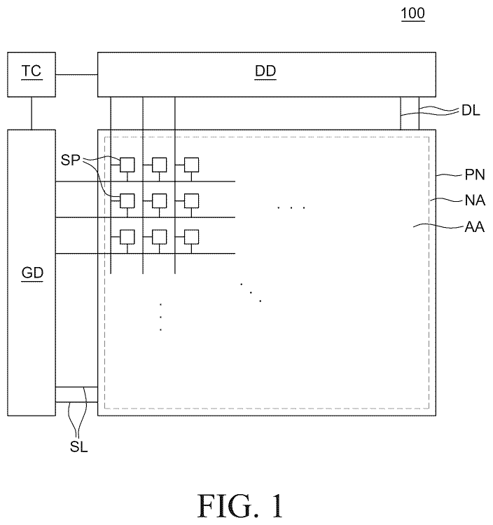

FIG. 1 is a schematic configuration view of a display device according to one or more embodiments of the present disclosure. For convenience of description, FIG. 1 illustrates only a display panel PN, a gate drive part GD, a data drive part DD, and a timing controller TC among various constituent elements of a display device 100.

With reference to FIG. 1, the display device 100 includes the display panel PN including a plurality of sub-pixels SP, the data drive part DD and the gate drive part GD configured to supply various types of signals to the display panel PN, and the timing controller TC configured to control the gate drive part GD, and the data drive part DD.

The gate drive part GD supplies a plurality of scan signals to a plurality of scan lines SL in response to a plurality of gate control signals provided from the timing controller TC. FIG. 1 illustrates that the single gate drive part GD is disposed to be spaced apart from one side of the display panel PN. However, the number and arrangement of the gate drive part GD are not limited thereto. For example, the gate drive part GD may be disposed at one or two sides of the display panel PN in Gate in Panel (GIP) manner, or may be disposed within the display area of the display panel PN in a gate-in-active area (GIA) manner, and the present disclosure is not limited thereto.

The data drive part DD supplies data voltages to a plurality of data lines DL in response to a plurality of data control signals and image data provided from the timing controller TC. The data drive part DD may convert image data into data voltages by using a reference gamma voltage and supply the converted data voltages to the plurality of data lines DL.

The timing controller TC aligns image data, which are inputted from the outside, and supplies the image data to the data drive part DD. The timing controller TC may generate the gate control signals and the data control signals by using synchronizing signals, e.g., dot clock signals, data enable signals, and horizontal/vertical synchronizing signals inputted from the outside. Further, the timing controller TC may control the gate drive part GD and the data drive part DD by supplying the generated gate control signals and data control signals to the gate drive part GD and the data drive part DD respectively.

The display panel PN is configured to display images to a user and includes the plurality of sub-pixels SP. In the display panel PN, the plurality of scan lines SL and the plurality of data lines DL may intersect one another, and the plurality of sub-pixels SP may be formed at intersection points between the scan line SL and the data line DL.

A display area AA and a non-display area NA may be defined on the display panel PN.

The display area AA is an area of the display device 100 in which images are displayed. The display area AA may include the plurality of sub-pixels SP constituting a plurality of pixels PX, and a pixel circuit configured to operate the plurality of sub-pixels SP. The plurality of sub-pixels SP is minimum units that constitute the display area AA. The n sub-pixels SP may constitute a single pixel PX. Thin-film transistors and the like for operating a plurality of light-emitting elements 120 may be respectively disposed in the plurality of sub-pixels SP. The plurality of light-emitting elements 120 may be differently defined depending on the type of display panel PN. For example, in case that the display panel PN is an inorganic light-emitting display panel PN, the light-emitting element 120 may be a light-emitting diode (LED) or a micro light-emitting diode (micro-LED).

A plurality of signal lines for transmitting various types of signals to the plurality of sub-pixels SP is disposed in the display area AA. For example, the plurality of signal lines may include the plurality of data lines DL for supplying data voltages to the plurality of sub-pixels SP, and the plurality of scan lines SL for supplying scan signals to the plurality of sub-pixels SP. The plurality of scan lines SL may extend in one direction in the display area AA and be connected to the plurality of sub-pixels SP. The plurality of data lines DL may extend in a direction different from one direction in which the scan lines extend in the display area AA and be connected to the plurality of sub-pixels SP. In addition, a low-potential power line VSS, a high-potential power line VDD, and the like may be further disposed in the display area AA. However, the present disclosure is not limited thereto.

The non-display area NA may be defined as an area in which no image is displayed, e.g., an area adjacent to, extending from the display area AA. The non-display area NA may include link lines and pad electrodes for transmitting signals to the sub-pixels SP in the display area AA. Alternatively, the non-display area NA may include drive ICs such as gate drivers IC and data drivers IC.

In addition, the non-display area NA may be positioned on a rear surface of the display panel PN, e.g., a surface on which the sub-pixel SP is not present. Alternatively, the non-display area NA may be excluded. However, the present disclosure is not limited to the configuration illustrated in the drawings.

In addition, the drive parts such as the gate drive part GD, the data drive part DD, and the timing controller TC may be connected to the display panel PN in various ways. For example, the gate drive part GD may be mounted in the non-display area NA by a gate-in-panel (GIP) method or mounted between the plurality of sub-pixels SP by a gate-in-active area (GIA) method in the display area AA.

For example, the data drive part DD and the timing controller TC may be formed on a separate flexible film and a printed circuit board and electrically connect the display panel PN, the data drive part DD, and the timing controller TC by a method of bonding the flexible film and the printed circuit board to a pad electrode formed in the non-display area NA of the display panel PN.

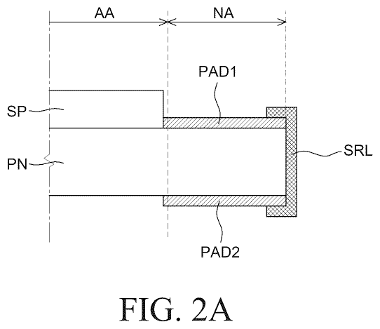

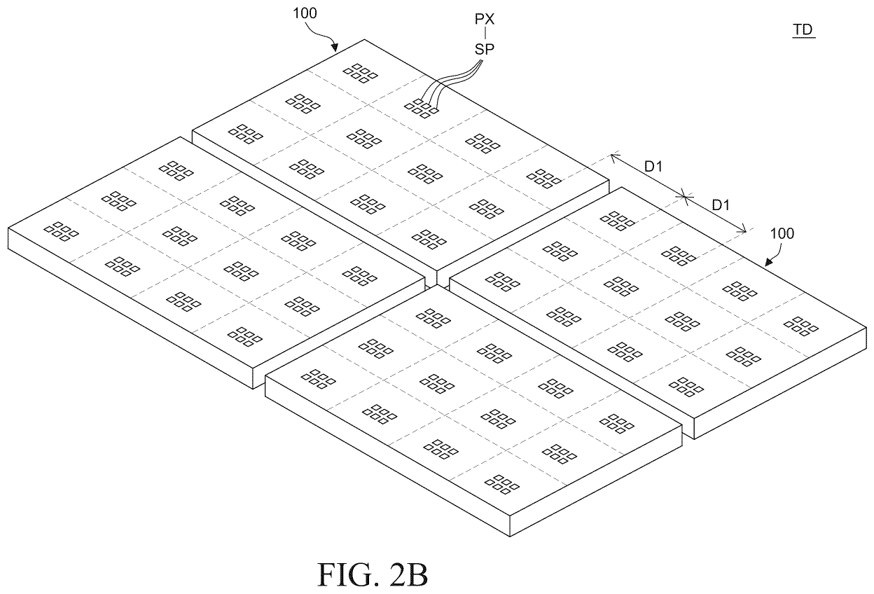

As another example, in case that the gate drive part GD is mounted in the display area AA by the GIA method and a side line SRL connects a signal line on a front surface of the display panel PN to the pad electrode on the rear surface of the display panel PN, which is formed to bond the flexible film and the printed circuit board to the rear surface of the display panel PN, it is possible to reduce the non-display area NA on the front surface of the display panel PN. Therefore, in case that the gate drive part GD, the data drive part DD, and the timing controller TC are connected to the display panel PN by the above-mentioned method, a zero bezel in which the bezel is not substantially present may be implemented. A more detailed description will be described with reference to FIGS. 2A and 2B.

FIG. 2A is a partial cross-sectional view of the display device according to one or more embodiments of the present disclosure. FIG. 2B is a perspective view of a tiling display device according to one or more embodiments of the present disclosure.

A plurality of pad electrodes for transmitting various types of signals to the plurality of sub-pixels SP are disposed in the non-display area NA of the display panel PN. For example, a first pad electrode PAD1 configured to transmit signals to the plurality of sub-pixels SP is disposed in the non-display area NA on the front surface of the display panel PN. A second pad electrode PAD2 electrically connected to drive components such as the flexible film and the printed circuit board is disposed in the non-display area NA on the rear surface of the display panel PN.

In this case, although not illustrated in the drawings, various types of signal lines, e.g., the scan line SL, the data line DL, or the like connected to the plurality of sub-pixels SP may extend from the display area AA to the non-display area NA and be electrically connected to the first pad electrode PAD1.

Further, the side line SRL is disposed along a side surface of the display panel PN. The side line SRL may electrically connect the first pad electrode PAD1 on the front surface of the display panel PN and the second pad electrode PAD2 on the rear surface of the display panel PN. Therefore, the signals received from the drive components on the rear surface of the display panel PN may be transmitted to the plurality of sub-pixels SP through the second pad electrode PAD2, the side line SRL, and the first pad electrode PAD1. Therefore, the drive component is disposed on the rear surface of the display panel PN, and a signal transmission route is defined between the front and rear surfaces of the display panel PN, which may minimize or at least reduce an area of the non-display area NA on the front surface of the display panel PN.

Further, with reference to FIG. 2B, a tiling display device TD having a large screen may be implemented by connecting or combining a plurality of display devices 100. In this case, as illustrated in FIG. 2A, in case that the tiling display device TD is implemented by using the display device 100 with the minimized or at least reduced bezel, a seam area in which no image is displayed between the display devices 100 may be minimized or at least reduced, thereby improving display quality.

For example, one pixel PX may include the plurality of sub-pixels SP. An interval D1 between an outermost peripheral pixel PX of one display device 100 and an outermost peripheral pixel PX of another display device 100 adjacent to one display device 100 may be implemented to be equal to the interval DI between the pixels PX in one display device 100. Therefore, the seam area may be minimized or at least reduced as a constant interval of the pixels PX is implemented between the display device 100 and the display device 100.

However, as illustrated in FIG. 2A and FIG. 2B, the display device 100 according to one or more embodiments of the present disclosure may be a general display device in which the bezel is present. However, the present disclosure is not limited thereto.

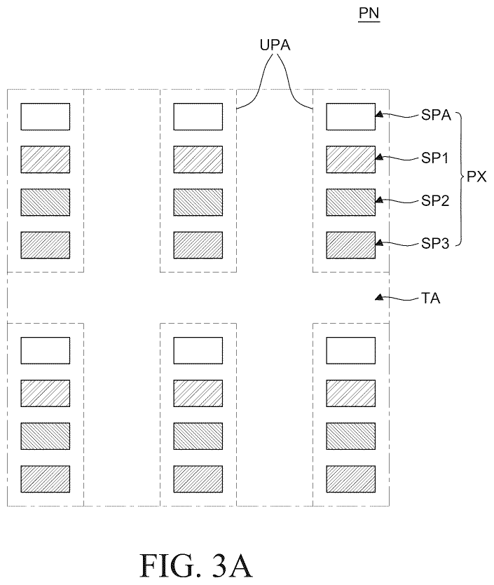

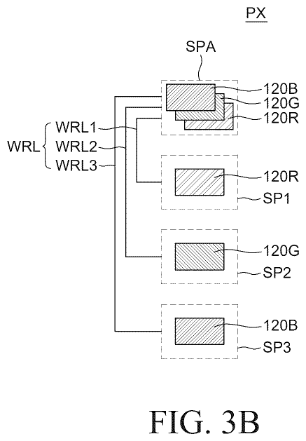

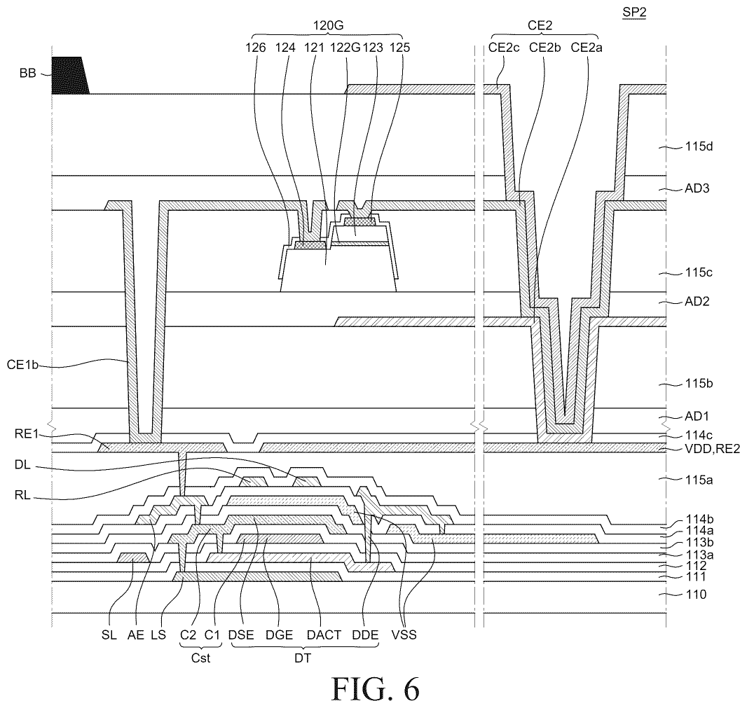

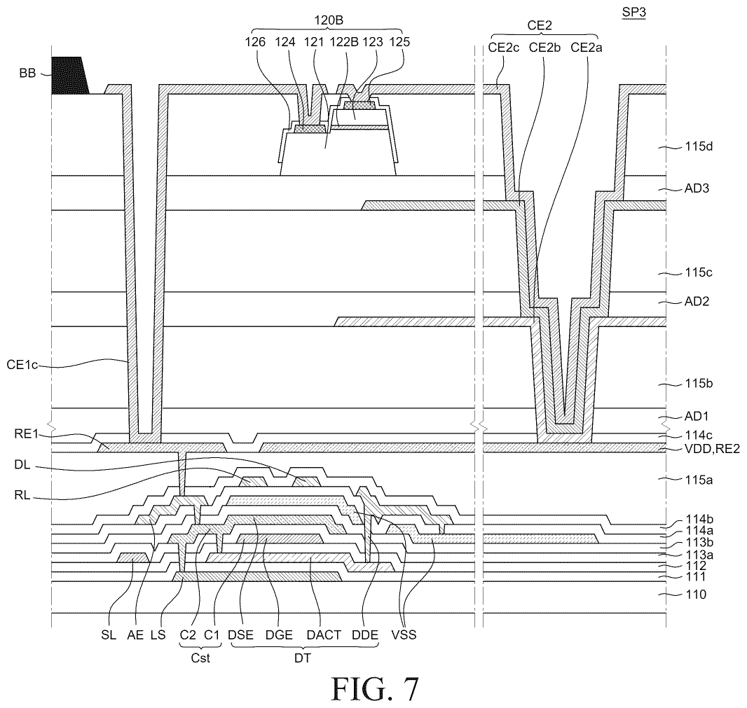

Hereinafter, the display panel PN of the display device 100 according to one or more embodiments of the present disclosure will be more specifically described with reference to FIGS. 3A to 10.

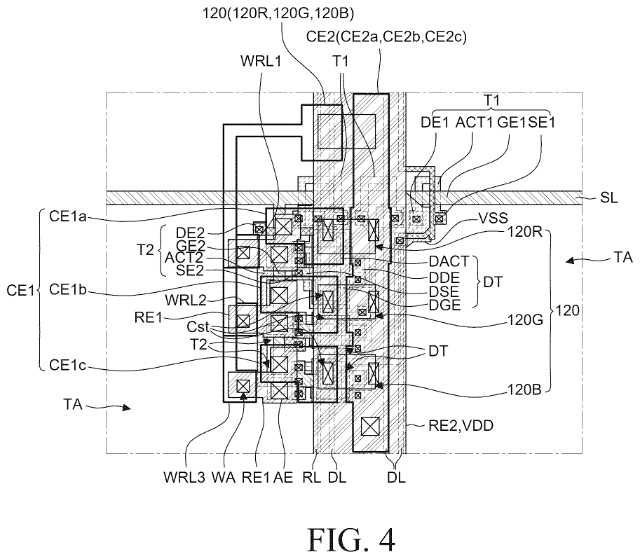

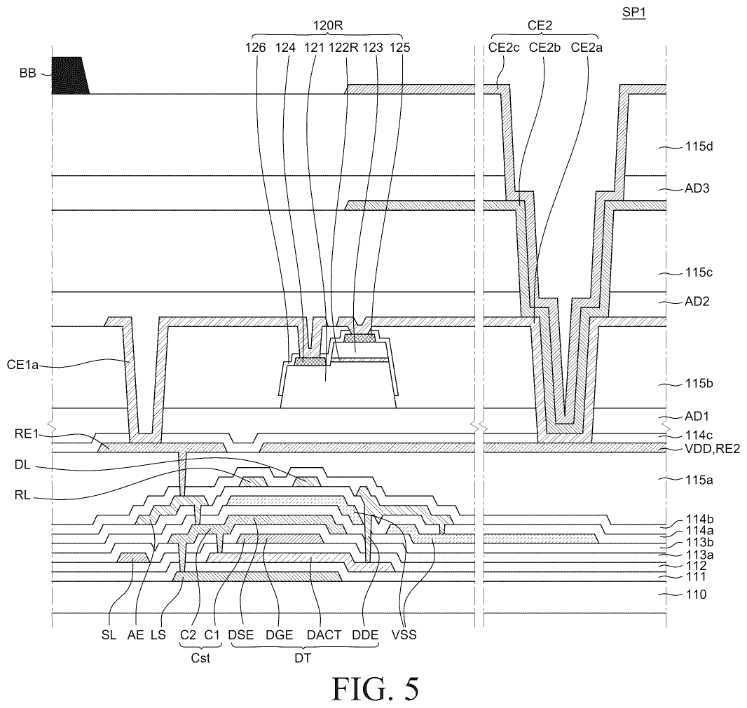

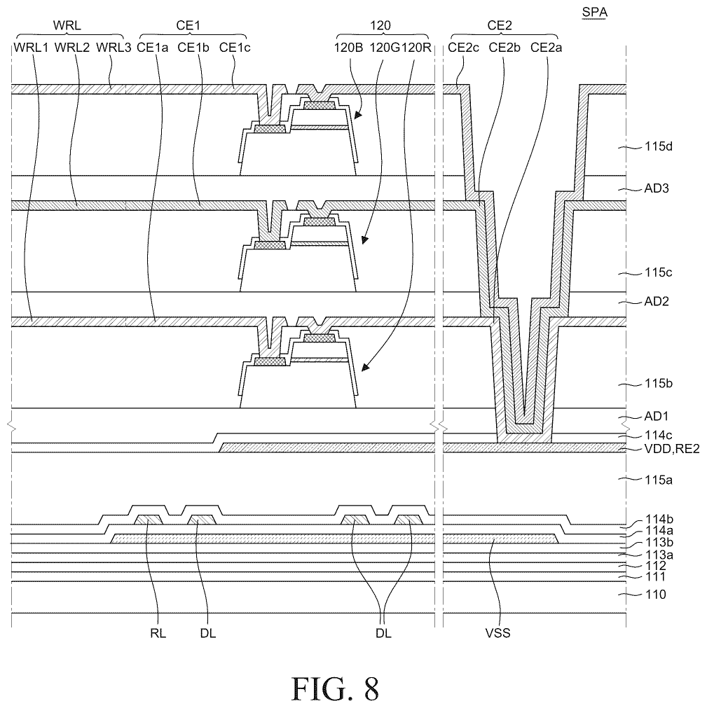

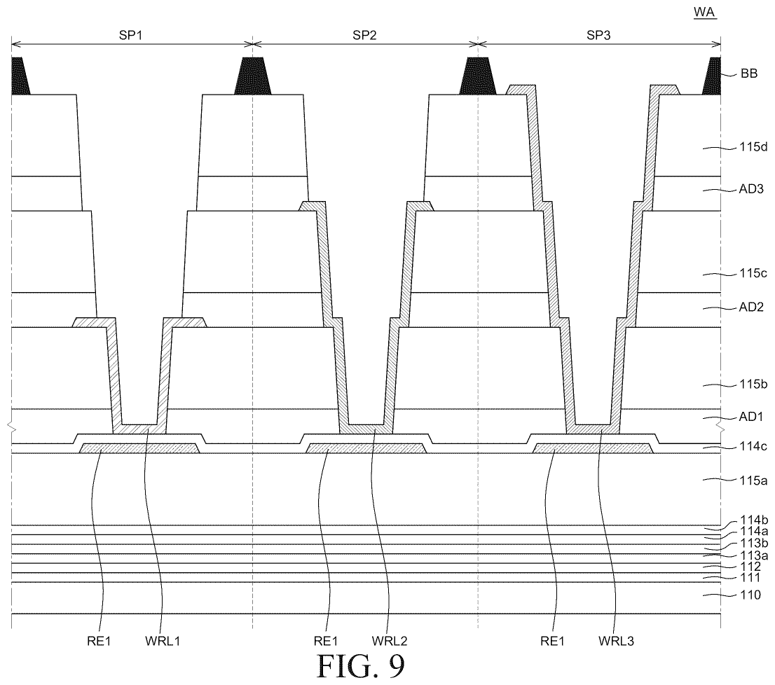

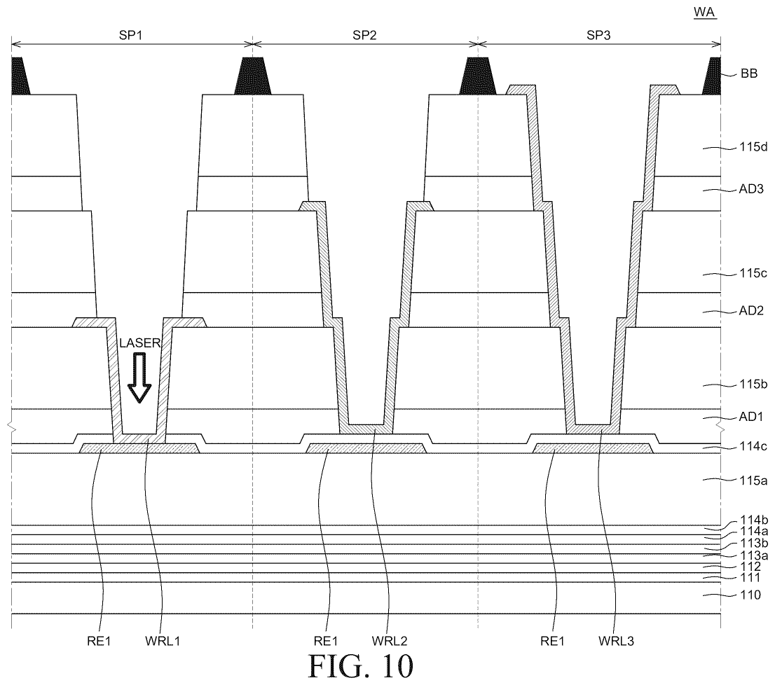

FIG. 3A is a schematic enlarged top plan view of the display area of the display device according to one or more embodiments of the present disclosure. FIG. 3B is a schematic configuration view of a pixel of the display device according to one or more embodiments of the present disclosure. FIG. 4 is an enlarged top plan view of the display area of the display device according to one or more embodiments of the present disclosure. FIGS. 5 to 7 are cross-sectional views of the plurality of sub-pixels of the display device according to one or more embodiments of the present disclosure. FIG. 8 is a cross-sectional view of a reserve sub-pixel of the display device according to one or more embodiments of the present disclosure. FIGS. 9 and 10 are cross-sectional views of a welding area of the display device according to one or more embodiments of the present disclosure. Specifically, FIGS. 5 to 7 are cross-sectional views of a first sub-pixel SP1, a second sub-pixel SP2, and a third sub-pixel SP3. FIGS. 9 and 10 are cross-sectional views of a welding area WA before and after a welding process.

With reference to FIGS. 3A and 3B, the display area AA has a pixel area UPA in which the pixel PX is formed, and a transmissive area TA configured to surround the pixel area UPA. The display area AA includes a plurality of pixel areas UPA and a plurality of transmissive areas TA. However, the present disclosure is not limited thereto, and the plurality of transmissive areas TA may be omitted from the display device of the present application.

The pixel circuit, which includes driving elements, and the light-emitting element 120, which is operated by the pixel circuit, are formed in the pixel PX in the display area AA, such that the plurality of pixel areas UPA, in which the pixels PX are formed, may be substantially opaque areas, and the plurality of transmissive areas TA, in which the pixel PX is not formed, may be substantially transparent areas. In this case, the pixel area UPA, which is defined as having the pixel PX, is an area in which light emitted from the light-emitting element 120 is displayed. Therefore, the pixel area UPA may be defined as a light-emitting area. In addition, the pixel area UPA, which is defined as having the pixel PX, is an area in which the pixel circuit including the driving element is formed. Therefore, the pixel area UPA may also be defined as a circuit area.

The pixel area UPA is an area in which the driving element and the light-emitting element 120 are disposed to display images. The plurality of pixel areas UPA may be disposed to be spaced apart from one another with the transmissive area TA interposed therebetween. For example, the plurality of pixel areas UPA may be disposed in a plurality of rows and a plurality of columns.

The pixel PX including the plurality of sub-pixels SP and a plurality of reserve sub-pixels SPA is disposed in each of the plurality of pixel areas UPA. The plurality of sub-pixels SP may each include the light-emitting element 120 and the pixel circuit and independently emit light. For example, the plurality of sub-pixels SP may include the first sub-pixels SP1, the second sub-pixels SP2, and the third sub-pixels SP3 that emit light beams with different colors. For example, the first sub-pixel SP1 may be a red sub-pixel SP, the second sub-pixel SP2 may be a green sub-pixel SP, and the third sub-pixel SP3 may be a blue sub-pixel SP. However, the present disclosure is not limited thereto. For example, the different color sub-pixels within the pixel PX can have different arrangements.

The reserve sub-pixel SPA is a sub-pixel SP configured to be used when any one of the first sub-pixel SP1, the second sub-pixel SP2, and the third sub-pixel SP3 of the plurality of sub-pixels SP is defective. For example, the reserve sub-pixel SPA may be used to repair a defective sub-pixel SP. The reserve sub-pixel SPA may include the plurality of light-emitting elements 120 and be used as any one of the first sub-pixel SP1, the second sub-pixel SP2, and the third sub-pixel SP3. When a defective sub-pixel SP occurs, one of the plurality of light-emitting elements 120 of the reserve sub-pixel SPA may be electrically connected to a driving transistor DT of the defective sub-pixel SP and operate.

For example, with reference to FIG. 3B, a red light-emitting element 120R may be disposed in the first sub-pixel SP1, a green light-emitting element 120G may be disposed in the second sub-pixel SP2, a blue light-emitting element 120B may be disposed in the third sub-pixel SP3, and all the red light-emitting element 120R, the green light-emitting element 120G, and the blue light-emitting element 120B may be disposed in the reserve sub-pixel SPA. Further, in case that a defect occurs on the red light-emitting element 120R of the first sub-pixel SP1 among the plurality of sub-pixels SP, the red light-emitting element 120R of the reserve sub-pixel SPA and the driving transistor DT of the first sub-pixel SP1 may be electrically connected to operate the red light-emitting element 120R of the reserve sub-pixel SPA to emit light. In this case, in order to reduce an area occupied by the reserve sub-pixel SPA, the red light-emitting element 120R, the green light-emitting element 120G, and the blue light-emitting element 120B may be vertically stacked in the reserve sub-pixel SPA. A more detailed description thereof will be described below with reference to FIGS. 4 to 8.

Hereinafter, the description will be made on the assumption that one pixel PX includes one first sub-pixel SP1, one second sub-pixel SP2, one third sub-pixel SP3, and one reserve sub-pixel SPA, e.g., includes one red sub-pixel SP, one green sub-pixel SP, one blue sub-pixel SP, and one reserve sub-pixel SPA. However, the configuration of the pixel PX is not limited thereto.

The pixel area UPA may overlap lines, which extend in a column direction among a plurality of lines, e.g., the data line DL, a reference line RL, the low-potential power line VSS, and the high-potential power line VDD. The pixel area UPA may be formed in an area in which a plurality of opaque lines is disposed, such that an area of the transmissive area TA may be ensured in the entire display area AA. Specifically, the pixel area UPA may be an area that has a low transmittance rate and is substantially opaque because of the configurations of the pixel circuits, the light-emitting elements 120, and the like disposed in the plurality of sub-pixels SP. Therefore, the plurality of sub-pixels SP in the pixel area UPA may be disposed to overlap the opaque lines extending in the column direction, e.g., the data line DL, the reference line RL, the low-potential power line VSS, and the high-potential power line VDD. Therefore, the plurality of sub-pixels SP in the pixel area UPA are disposed to overlap the plurality of lines, such that an area of the opaque area may be reduced in the entire display area AA, and a maximum or at least increased area of the transmissive area TA may be ensured.

The transmissive area TA may be an area excluding the area in which the plurality of lines and the plurality of pixel areas UPA are disposed in the display area AA. The transmissive area TA has a relatively high transmittance rate. The transmissive area TA transmits light, such that a background positioned on the rear surface of the display device 100 is visible from the front surface of the display device 100. The plurality of transmissive areas TA may be disposed to be spaced apart from one another with the plurality of lines and the plurality of pixel areas UPA interposed therebetween. The plurality of transmissive areas TA may be disposed to surround the plurality of pixel areas UPA. Therefore, the display device 100 according to one or more embodiments of the present disclosure may be implemented as the transparent display device 100 including the plurality of transmissive areas TA.

With reference to FIGS. 3A to 5, the plurality of sub-pixels SP each includes the pixel circuit and one or more light-emitting elements 120. The pixel circuit may include a plurality of transistors such as T1, T2, and DT and a storage capacitor Cst and supply a drive current to the light-emitting element 120. For example, the pixel circuit may include a first transistor T1, a second transistor T2, the driving transistor DT, and the storage capacitor Cst. Further, the plurality of sub-pixels SP disposed in one pixel area UPA may be connected to the scan line SL, the plurality of data lines DL, the reference line RL, the high-potential power line VDD, and the low-potential power line VSS and supplied with various types of signals. However, the present disclosure is not limited thereto, and the pixel circuit may include more or less elements than shown. An example illustrated in FIG. 4 represents 3T1C structure that where three transistors and one capacitor are disposed, but embodiments of the present disclosure are not limited to this. For example, 3T2C, 4T1C, 5T1C, 3T2C, 5T2C, 4T2C, 6T2C, 7TIC, 7T2C, 8T2C structures, etc. are also possible. And more or less transistors and capacitors could be included.

First, a substrate 110 is a component for supporting various constituent elements included in the display device 100 and may be made of an insulating material. For example, the substrate 110 may be made of glass, resin, or the like. In addition, the substrate 110 may include plastic such as polymer and may be made of a material having flexibility.

A light-blocking layer LS is disposed on each of the plurality of sub-pixels SP on the substrate 110. The light-blocking layer LS blocks light entering a driving active layer DACT of the driving transistor DT, which will be described below, from a lower side of the substrate 110. The light-blocking layer LS may block light entering the driving active layer DACT of the driving transistor DT, thereby minimizing or at least reducing a leakage current.

A buffer layer 111 is disposed on the substrate 110 and the light-blocking layer LS. The buffer layer 111 may reduce the penetration of moisture or impurities through the substrate 110. For example, the buffer layer 111 may be configured as a single layer or multilayer made of silicon oxide (SiOx) or silicon nitride (SiNx). However, the present disclosure is not limited thereto. However, the buffer layer 111 may be excluded in accordance with the type of substrate 110 or the type of transistor. However, the present disclosure is not limited thereto.

The driving transistor DT, the first transistor T1, and the second transistor T2 are disposed in each of the plurality of sub-pixels SP on the buffer layer 111.

The driving transistor DT, the first transistor T1, and the second transistor T2 of each of the plurality of sub-pixels SP may be P-type thin-film transistors or N-type thin-film transistors. For example, in the P-type thin-film transistor, positive holes move from a source electrode to a drain electrode, such that current may flow from the source electrode to the drain electrode. In the N-type thin-film transistor, electrons move from a source electrode to a drain electrode, such that current may flow from the drain electrode to the source electrode. Hereinafter, the description will be made on the assumption that the driving transistor DT, the first transistor T1, and the second transistor T2 are the P-type thin-film transistors in which the current flows from the source electrodes to the drain electrodes. However, the present disclosure is not limited thereto.

Secondly, the driving transistor DT is disposed in each of the plurality of sub-pixels SP on the buffer layer 111. The driving transistor DT is a transistor for controlling a drive current to be supplied to the light-emitting element 120. In one pixel area UPA, the driving transistors DT of the plurality of sub-pixels SP may be disposed in a line in the column direction. The plurality of driving transistors DT of the plurality of sub-pixels SP may be disposed in a line while overlapping the areas in which the reference lines RL and the data lines DL are disposed.

The driving transistor DT includes the driving active layer DACT, a driving gate electrode DGE, a driving source electrode DSE, and a driving drain electrode DDE.

The driving active layer DACT is disposed on the buffer layer 111. The driving active layer DACT may be made of a semiconductor material such as an oxide semiconductor, amorphous silicon, or polysilicon. However, the present disclosure is not limited thereto. The oxide semiconductor may be made of a metal oxide such as zinc (Zn), indium (In), gallium (Ga), tin (Sn), and titanium (Ti) or a combination of a metal such as zinc (Zn), indium (In), gallium (Ga), tin (Sn), or titanium (Ti) and its oxide. Specifically, the oxide semiconductor may include zinc oxide (ZnO), zinc-tin oxide (ZTO), zinc-indium oxide (ZIO), indium oxide (InO), titanium oxide (TiO), indium-gallium-zinc oxide (IGZO), indium-zinc-tin oxide (IZTO), indium zinc oxide (IZO), indium gallium tin oxide (IGTO), and indium gallium oxide (IGO), but is not limited thereto.

A gate insulation layer 112 is disposed on the driving active layer DACT. The gate insulation layer 112 is an insulation layer for insulating the driving active layer DACT and the driving gate electrode DGE from each other. The gate insulation layer 112 may be configured as a single layer or multilayer made of silicon oxide (SiOx) or silicon nitride (SiNx). However, the present disclosure is not limited thereto.

The driving gate electrode DGE is disposed on the gate insulation layer 112. The driving gate electrode DGE may be configured as a single layer or multilayer made of an electrically conductive material, for example, copper (Cu), aluminum (Al), molybdenum (Mo), nickel (Ni), titanium (Ti), chromium (Cr), or an alloy thereof. However, the present disclosure is not limited thereto. For example, although the driving transistor DT is shown as a top gate type in FIG. 5, the driving transistor DT may also be implemented with a bottom gate type or a dual gate type in other examples.

A first interlayer insulation layer 113a is disposed on the driving gate electrode DGE. A contact hole, through which the driving source electrode DSE is connected to the driving active layer DACT, is formed in the first interlayer insulation layer 113a. The first interlayer insulation layer 113a is an insulation layer for protecting components disposed below the first interlayer insulation layer 113a. The first interlayer insulation layer 113a may be configured as a single layer or multilayer made of silicon oxide (SiOx) or silicon nitride (SiNx). However, the present disclosure is not limited thereto.

The driving source electrode DSE is disposed on the first interlayer insulation layer 113a. The driving source electrode DSE is electrically connected to the driving active layer DACT through a contact hole formed in the first interlayer insulation layer 113a. Further, the driving source electrode DSE may be electrically connected to the second transistor T2. The driving source electrode DSE may be configured as a single layer or multilayer made of an electrically conductive material, for example, copper (Cu), aluminum (Al), molybdenum (Mo), nickel (Ni), titanium (Ti), chromium (Cr), or an alloy thereof. However, the present disclosure is not limited thereto.

A second interlayer insulation layer 113b is disposed on the driving source electrode DSE. The second interlayer insulation layer 113b is an insulation layer for protecting components disposed below the second interlayer insulation layer 113b. The second interlayer insulation layer 113b may be configured as a single layer or multilayer made of silicon oxide (SiOx) or silicon nitride (SiNx). However, the present disclosure is not limited thereto.

A first passivation layer 114a is disposed on the second interlayer insulation layer 113b. The first passivation layer 114a is an insulation layer for protecting components disposed below the first passivation layer 114a. The first passivation layer 114a may be configured as a single layer or multilayer made of silicon oxide (SiOx) or silicon nitride (SiNx). However, the present disclosure is not limited thereto.

The driving drain electrode DDE is disposed on the first passivation layer 114a. The driving drain electrode DDE is electrically connected to the driving active layer DACT through contact holes formed in the first passivation layer 114a, the first interlayer insulation layer 113a, and the second interlayer insulation layer 113b. Further, the driving drain electrode DDE may be electrically connected to the low-potential power line VSS through a contact hole formed in the first passivation layer 114a. The driving drain electrode DDE may be configured as a single layer or multilayer made of an electrically conductive material, for example, copper (Cu), aluminum (Al), molybdenum (Mo), nickel (Ni), titanium (Ti), chromium (Cr), or an alloy thereof. However, the present disclosure is not limited thereto.

Next, the first transistor T1 is disposed on the buffer layer 111 in each of the plurality of sub-pixels SP. The first transistor T1 may be a transistor configured to transmit a data voltage Vdata to a gate electrode of the driving transistor DT. The first transistor T1 may be referred to as a switching transistor. In this case, in one pixel area UPA, the plurality of first transistors T1 of the plurality of sub-pixels SP may be disposed to overlap the scan line SL and a protruding part of the scan line SL and disposed in a line in a row direction.

Specifically, the scan line SL may extend in the row direction on the gate insulation layer 112 and be disposed to traverse the plurality of pixel areas UPA. In this case, the scan line SL may include the protruding part protruding in the column direction toward the plurality of sub-pixels SP in the area that overlaps the plurality of pixel areas UPA.

The first transistors T1 of the plurality of sub-pixels SP may be disposed in a line in the area in which the scan line SL is disposed. The first transistor T1 of the first sub-pixel SP1, the first transistor T1 of the second sub-pixel SP2, and the first transistor T1 of the third sub-pixel SP3 may be disposed in a line in the row direction in the area in which the scan line SL is disposed.

The first transistor T1 includes a first active layer ACT1, a first gate electrode GE1, a first source electrode SE1, and a first drain electrode DE1.

The first active layer ACTI is disposed on the buffer layer 111. The first active layer ACTI may be made of a semiconductor material such as an oxide semiconductor, amorphous silicon, or polysilicon. However, the present disclosure is not limited thereto.

The first gate electrode GE1 is disposed on the gate insulation layer 112. The first gate electrode GE1 may be electrically connected to the scan line SL. For example, the first gate electrode GE1 may be integrated with the scan line SL. The first gate electrode GE1 may be configured as a single layer or multilayer made of an electrically conductive material, for example, copper (Cu), aluminum (Al), molybdenum (Mo), nickel (Ni), titanium (Ti), chromium (Cr), or an alloy thereof. However, the present disclosure is not limited thereto.

The first drain electrode DE1 is disposed between the first interlayer insulation layer 113a and the second interlayer insulation layer 113b. The first drain electrode DE1 is electrically connected to the first active layer ACT1 through contact holes formed in the first interlayer insulation layer 113a and the gate insulation layer 112. Further, the first drain electrode DE1 may be electrically connected to a second gate electrode GE2 of the second transistor T2 through the contact hole of the first interlayer insulation layer 113a. The first drain electrode DE1 may be configured as a single layer or multilayer made of an electrically conductive material, for example, copper (Cu), aluminum (Al), molybdenum (Mo), nickel (Ni), titanium (Ti), chromium (Cr), or an alloy thereof. However, the present disclosure is not limited thereto.

The first source electrode SE1 is disposed on the first passivation layer 114a. The first source electrode SE1 is electrically connected to the first active layer ACT1 through the contact holes of the first passivation layer 114a, the second interlayer insulation layer 113b, and the first interlayer insulation layer 113a. Further, the first source electrode SE1 may be electrically connected to the data line DL. For example, the first source electrode SE1 may be integrated with the data line DL. The first source electrode SE1 may be configured as a single layer or multilayer made of an electrically conductive material, for example, copper (Cu), aluminum (Al), molybdenum (Mo), nickel (Ni), titanium (Ti), chromium (Cr), or an alloy thereof. However, the present disclosure is not limited thereto.

Next, the second transistor T2 is disposed on the buffer layer 111 in each of the plurality of sub-pixels SP. The second transistor T2 may be a transistor configured to compensate for a threshold voltage of the driving transistor DT. The second transistor T2 may be referred to as a sensing transistor. The second transistors T2 of the plurality of sub-pixels SP may be disposed in a line along the protruding part of the scan line SL that protrudes in the column direction. For example, the second transistors T2 of the plurality of sub-pixels SP may be disposed to correspond to the protruding part of the scan line SL that protrudes in the column direction. Therefore, the plurality of second transistors T2 disposed in one pixel area UPA may be disposed in a line in the column direction.

The second transistor T2 includes a second active layer ACT2, the second gate electrode GE2, a second source electrode SE2, and a second drain electrode DE2.

The second active layer ACT2 is disposed between the buffer layer 111 and the gate insulation layer 112. The second active layer ACT2 may be made of a semiconductor material such as an oxide semiconductor, amorphous silicon, or polysilicon. However, the present disclosure is not limited thereto.

In this case, the second active layers ACT2 of the plurality of adjacent sub-pixels SP may be connected to one another. For example, the second active layers ACT2 of the first sub-pixel SP1, the second sub-pixel SP2, and the third sub-pixel SP3 may extend in the column direction and be connected to one another, and the second active layers ACT2 may be connected together to the second drain electrode DE2 disposed in the first sub-pixel SP1. For example, connection parts for connecting the reference line RL and channel areas of the second active layers ACT2 of the plurality of sub-pixels SP are made of the transparent material of the second active layer ACT2, instead of an opaque electrically conductive material, such that a transmittance rate may be increased at an outermost periphery of the pixel area UPA. In addition, the connection parts for connecting the reference line RL and the channel areas of the second active layers ACT2 of the plurality of sub-pixels SP are made of the material of the second active layer ACT2, such that the contact hole may be eliminated, and the structure of the pixel area UPA may be simplified.

The second gate electrode GE2 is disposed between the gate insulation layer 112 and the first interlayer insulation layer 113a. The second gate electrode GE2 may be electrically connected to the scan line SL. For example, the second gate electrode GE2 may be integrated with the protruding part of the scan line SL and electrically connected to the protruding part of the scan line SL. The second gate electrode GE2 may be configured as a single layer or multilayer made of an electrically conductive material, for example, copper (Cu), aluminum (Al), molybdenum (Mo), nickel (Ni), titanium (Ti), chromium (Cr), or an alloy thereof. However, the present disclosure is not limited thereto.

The second source electrode SE2 is disposed between the first interlayer insulation layer 113a and the second interlayer insulation layer 113b. The second source electrode SE2 is electrically connected to the second active layer ACT2 through the contact holes of the first interlayer insulation layer 113a and the gate insulation layer 112. Further, the second source electrode SE2 may be integrated with the driving source electrode DSE and electrically connected to the driving source electrode DSE. The second source electrode SE2 may be configured as a single layer or multilayer made of an electrically conductive material, for example, copper (Cu), aluminum (Al), molybdenum (Mo), nickel (Ni), titanium (Ti), chromium (Cr), or an alloy thereof. However, the present disclosure is not limited thereto.

The second drain electrode DE2 is disposed between the first passivation layer 114a and a second passivation layer 114b. The second drain electrode DE2 is electrically connected to the second active layer ACT2 through contact holes formed in the first passivation layer 114a, the second interlayer insulation layer 113b, the first interlayer insulation layer 113a, and the gate insulation layer 112. The second drain electrode DE2 may be integrated with the reference line RL and electrically connected to the reference line RL. The second drain electrode DE2 may be configured as a single layer or multilayer made of an electrically conductive material, for example, copper (Cu), aluminum (Al), molybdenum (Mo), nickel (Ni), titanium (Ti), chromium (Cr), or an alloy thereof. However, the present disclosure is not limited thereto.

Next, the storage capacitor Cst is disposed on the gate insulation layer 112. The storage capacitor Cst may store a potential difference between the driving gate electrode DGE and the driving source electrode DSE of the driving transistor DT while the light-emitting element 120 emits light, such that a constant drive current may be supplied to the light-emitting element 120. The storage capacitor Cst may include a first capacitor electrode C1 electrically connected to the driving gate electrode DGE, and a second capacitor electrode C2 electrically connected to the driving source electrode DSE. The storage capacitor Cst may maintain constant voltages of the driving gate electrode DGE and the driving source electrode DSE.

Specifically, the first capacitor electrode C1 is disposed on the gate insulation layer 112. The first capacitor electrode C1 may be integrated with the driving gate electrode DGE. The second capacitor electrode C2 is disposed on the first interlayer insulation layer 113a. The first capacitor electrode C1 and the second capacitor electrode C2 may be disposed to overlap each other with the first interlayer insulation layer 113a interposed therebetween. In this case, the second capacitor electrode C2 may be integrated with the driving source electrode DSE. The first capacitor electrode C1 and the second capacitor electrode C2 may each be configured as a single layer or multilayer made of an electrically conductive material, for example, copper (Cu), aluminum (Al), molybdenum (Mo), nickel (Ni), titanium (Ti), chromium (Cr), or an alloy thereof. However, the present disclosure is not limited thereto.

Next, an auxiliary electrode AE is disposed on the first passivation layer 114a. The auxiliary electrode AE is an electrode for electrically connecting the driving source electrode DSE and a first reflective electrode RE1. The driving source electrode DSE and the first reflective electrode RE1 may be electrically connected to each other through the auxiliary electrode AE. The auxiliary electrode AE may be configured as a single layer or multilayer made of an electrically conductive material, for example, copper (Cu), aluminum (Al), molybdenum (Mo), nickel (Ni), titanium (Ti), chromium (Cr), or an alloy thereof. However, the present disclosure is not limited thereto. It is to be noted that the driving source electrode DSE may be directly connected with the first reflective electrode RE1, and thus the auxiliary electrode AE may be omitted.

The low-potential power line VSS is disposed on the second interlayer insulation layer 113b. The low-potential power line VSS may be disposed in the column direction and overlap the plurality of pixel areas UPA. The low-potential power line VSS may be electrically connected to the driving drain electrode DDE. The low-potential power line VSS may be configured as a single layer or multilayer made of an electrically conductive material, for example, copper (Cu), aluminum (Al), molybdenum (Mo), nickel (Ni), titanium (Ti), chromium (Cr), or an alloy thereof. However, the present disclosure is not limited thereto.

Further, the low-potential power line VSS may overlap the area in which the plurality of data lines DL is disposed. The low-potential power line VSS may have a relatively large width, such that one low-potential power line VSS and the plurality of data lines DL may overlap one another. The low-potential power line VSS may cover the storage capacitors Cst and the driving transistors DT of the plurality of sub-pixels SP. Because only the low-potential power line VSS is disposed between the second interlayer insulation layer 113b and the first passivation layer 114a, the low-potential power line VSS may be easily formed in an area excluding the area in which the contact hole is disposed.

An opening portion may be formed in the low-potential power line VSS and overlap the contact hole. For example, the opening portion may be formed in the low-potential power line VSS and overlap the contact hole, through which the first source electrode SE1 and the first active layer ACT1 are connected, and the contact hole through which the driving drain electrode DDE and the driving active layer DACT are connected. The first source electrode SE1 and the driving drain electrode DDE are disposed on the low-potential power line VSS, and the first active layer ACT1 and the driving active layer DACT are disposed below the low-potential power line VSS. Therefore, the opening portion is formed in the low-potential power line VSS, such that the components connected to the upper and lower portions of the low-potential power line VSS may be easily connected.

The low-potential power line VSS may be disposed between the storage capacitor Cst, the driving transistor DT, and the plurality of data lines DL and serve as a blocking film that suppresses a fluctuation of voltage of the driving transistor DT caused by the data line DL. The low-potential power line VSS, to which a predetermined constant voltage is applied, may be disposed between the storage capacitor Cst, the driving transistor DT, and the data line DL and inhibit the data line DL, the storage capacitor Cst, and the driving transistor DT from being coupled. The low-potential power line VSS may be disposed to at least cover the driving gate electrode DGE of the driving transistor DT and protect the driving gate electrode DGE so that the voltage of the driving gate electrode DGE is not fluctuated by the data line DL.

Next, the reference line RL is disposed on the first passivation layer 114a. The reference line RL may be disposed in the column direction and overlap the plurality of pixel areas UPA. The reference line RL may be disposed adjacent to the protruding part of the scan line SL and electrically connected to the plurality of second transistors T2 disposed on the protruding part of the scan line SL. The reference line RL may be configured as a single layer or multilayer made of an electrically conductive material, for example, copper (Cu), aluminum (Al), molybdenum (Mo), nickel (Ni), titanium (Ti), chromium (Cr), or an alloy thereof. However, the present disclosure is not limited thereto.

The plurality of data lines DL is disposed on the first passivation layer 114a. The plurality of data lines DL may extend in the column direction and overlap the plurality of pixel areas UPA. The plurality of data lines DL may include the data line DL connected to the first transistors T1 of the plurality of first sub-pixels SP1, the data line DL connected to the first transistors T1 of the plurality of second sub-pixels SP2, and the data line DL connected to the first transistors T1 of the plurality of third sub-pixels SP3.

Next, the second passivation layer 114b is disposed on the driving transistor DT, the first transistor T1, the second transistor T2, the storage capacitor Cst, the reference line RL, and the data line DL. The second passivation layer 114b may be an insulation layer for protecting components disposed below the second passivation layer 114b. The second passivation layer 114b may be configured as a single layer or multilayer made of silicon oxide (SiOx) or silicon nitride (SiNx). However, the present disclosure is not limited thereto.

A first planarization layer 115a is disposed on the second passivation layer 114b. The first planarization layer 115a may planarize an upper portion of the substrate 110 on which the plurality of transistors and the storage capacitor Cst are disposed. The first planarization layer 115a may be configured as a single layer or multilayer and made of a photoresist or an acrylic-based organic material, for example. However, the present disclosure is not limited thereto.

In addition, although not illustrated in the drawings, an additional passivation layer may be further disposed on the first planarization layer 115a. For example, the passivation layer, which is configured as a single layer or multilayer made of silicon oxide (SiOx) or silicon nitride (SiNx), may be disposed on the first planarization layer 115a and protect the components disposed below the passivation layer.

Next, the plurality of first reflective electrodes RE1 are disposed on the first planarization layer 115a. The plurality of first reflective electrodes RE1 may be respectively disposed in the plurality of sub-pixels SP and electrically connect the driving transistors DT and the light-emitting elements 120. In addition, the plurality of first reflective electrodes RE1 may reflect the light, which is emitted from the light-emitting elements 120, to the outside of the display device 100. The plurality of first reflective electrodes RE1 may be disposed adjacent to the driving source electrodes DSE in the plurality of sub-pixels SP. The first reflective electrode RE1 may be connected to the auxiliary electrode AE through contact holes formed in the first planarization layer 115a and the second passivation layer 114b. The first reflective electrode RE1 may be electrically connected to the driving source electrode DSE and the second source electrode SE2 through the auxiliary electrode AE. The plurality of first reflective electrodes RE1 may be made of an opaque conductive material such as titanium (Ti), gold (Au), silver (Ag), copper (Cu), or an alloy thereof with high reflection efficiency. However, the present disclosure is not limited thereto.

In this case, the contact hole, through which the first reflective electrode REI and the auxiliary electrode AE or the driving source electrode DSE are connected, may be disposed in the area in which a first connection electrode CE1 is not disposed. The contact hole, through which the first reflective electrode RE1 and the auxiliary electrode AE or the driving source electrode DSE are connected, and the contact hole, through which the first connection electrode CE1 and the first reflective electrode RE1 are connected, may be disposed on different areas or may be spaced apart from each other. In order to suppress a bright spot defect in which the light-emitting element 120 continuously emits light in case that a defect occurs on the light-emitting element 120, it is possible to block a drive current route between the defective light-emitting element 120 and the pixel circuit by damaging the portion where the first reflective electrode RE1 and the first connection electrode CE1 are connected. In this case, even though the portion where the first reflective electrode RE1 and the first connection electrode CE1 are connected is damaged, the portion where the first reflective electrode RE1 and the auxiliary electrode AE are connected may be kept in the connected state without being damaged. Thereafter, during a repair process, the first reflective electrode RE1 may electrically connect a repair line WRL and the driving transistor DT. A more detailed description of the repair process will be described below.

Next, a second reflective electrode RE2 or the high-potential power line VDD is disposed on the first planarization layer 115a. The second reflective electrode RE2 and the high-potential power line VDD may be integrated and configured to supply a high-potential power voltage to the light-emitting element 120 and reflect the light, which is emitted from the light-emitting element 120, to the outside of the display device 100. The second reflective electrodes RE2 of the plurality of sub-pixels SP may be connected to and integrated with one another. The second reflective electrode RE2 and the high-potential power line VDD may extend in the column direction and be disposed to overlap the light-emitting element 120. The second reflective electrode RE2 and the high-potential power line VDD may be disposed to overlap the plurality of data lines DL, the reference line RL, and the low-potential power line VSS. The second reflective electrode RE2 and the high-potential power line VDD may be made of an opaque conductive material such as titanium (Ti), gold (Au), silver (Ag), copper (Cu), or an alloy thereof with high reflection efficiency. However, the present disclosure is not limited thereto.

A third passivation layer 114c is disposed on the plurality of first reflective electrodes RE1 and the second reflective electrode RE2. The third passivation layer 114c may be an insulation layer for protecting components disposed below the third passivation layer 114c. The third passivation layer 114c may be configured as a single layer or multilayer made of silicon oxide (SiOx) or silicon nitride (SiNx). However, the present disclosure is not limited thereto.

A first bonding layer AD1 is disposed on the third passivation layer 114c. The first bonding layer AD1 may be formed on a front surface of the substrate 110 and fix the light-emitting element 120 disposed on the first bonding layer AD1. The first bonding layer AD1 may be made of a photocurable bonding material that may be cured by light. For example, the first bonding layer AD1 may be made of any one of adhesive polymer, epoxy resist, UV resin, a polyimide-based material, an acrylate-based material, a urethane-based material, and polydimethylsiloxane (PDMS). However, the present disclosure is not limited thereto.

The plurality of light-emitting elements 120 are provided on the first bonding layer AD1 and disposed in each of the plurality of sub-pixels SP. The light-emitting elements 120 may be elements configured to emit light by the current and include the red light-emitting element 120R configured to emit red light, the green light-emitting element 120G configured to emit green light, and the blue light-emitting element 120B configured to emit blue light. A combination of the light-emitting elements 120 may implement various colors including white. For example, the light-emitting element 120 may be a light-emitting diode (LED) or a micro-LED. However, the present disclosure is not limited thereto.

The red light-emitting element 120R may be disposed in the first sub-pixel SP1, the green light-emitting element 120G may be disposed in the second sub-pixel SP2, and the blue light-emitting element 120B may be disposed in the third sub-pixel SP3. The plurality of light-emitting elements 120 disposed in one pixel area UPA may be disposed in a line in the column direction. Further, the plurality of light-emitting elements 120 may be respectively disposed in the plurality of sub-pixels SP and disposed to overlap the second reflective electrode RE2.

In addition, the red light-emitting element 120R, the green light-emitting element 120G, and the blue light-emitting element 120B may be disposed on different layers. For example, the red light-emitting element 120R may be disposed on the first bonding layer AD1, the green light-emitting element 120G may be disposed on a second bonding layer AD2 formed on the red light-emitting element 120R, and the blue light-emitting element 120B may be disposed on a third bonding layer AD3 formed on the green light-emitting element 120G. In order to reduce the area of the reserve sub-pixel SPA, the red light-emitting element 120R, the green light-emitting element 120G, and the blue light-emitting element 120B may be vertically stacked in the reserve sub-pixel SPA. In this process, the light-emitting elements 120 of the plurality of sub-pixels SP may be transferred to different layers.

First, with reference to FIGS. 5 and 8 together, the red light-emitting element 120R is disposed on the first bonding layer AD1 and provided in each of the first sub-pixel SP1 and the reserve sub-pixel SPA. The red light-emitting element 120R includes a first semiconductor layer 121, a red light-emitting layer 122R, a second semiconductor layer 123, a first electrode 124, a second electrode 125, and an encapsulation film 126.

The first semiconductor layer 121 is disposed on the first bonding layer AD1, and the second semiconductor layer 123 is disposed on the first semiconductor layer 121. The first semiconductor layer 121 and the second semiconductor layer 123 may each be a layer formed by doping a particular material with n-type or p-type impurities. For example, the first semiconductor layer 121 and the second semiconductor layer 123 may each be a layer formed by doping a material, such as gallium nitride (GaN), indium aluminum phosphide (InAlP), or gallium arsenic (GaAs) with n-type or p-type impurities. Further, the p-type impurity may be magnesium, zinc (Zn), beryllium (Be), or the like. The n-type impurity may be silicon (Si), germanium, tin (Sn), or the like. However, the present disclosure is not limited thereto.

The red light-emitting layer 122R is disposed between the first semiconductor layer 121 and the second semiconductor layer 123. The red light-emitting layer 122R may emit light by receiving positive holes and electrons from the first semiconductor layer 121 and the second semiconductor layer 123. The red light-emitting layer 122R may be configured as a single layer or a multi-quantum well (MQW) structure. For example, the red light-emitting layer 122R may be made of gallium arsenide (GaAs), gallium arsenide nitride (GaAsP), indium gallium nitride (InGaN), gallium nitride (GaN), or the like. However, the present disclosure is not limited thereto.

The first electrode 124 is disposed on the first semiconductor layer 121. The first electrode 124 is an electrode that electrically connects the driving transistor DT and the first semiconductor layer 121. In this case, the first semiconductor layer 121 may be a semiconductor layer doped with n-type impurities, and the first electrode 124 may be a cathode. The first electrode 124 may be disposed on an upper surface (e.g., top surface) of the first semiconductor layer 121 exposed from the red light-emitting layer 122R and the second semiconductor layer 123. The first electrode 124 may be made of an electrically conductive material, for example, a transparent conductive material such as indium tin oxide (ITO) or indium zinc oxide (IZO) or an opaque conductive material such as titanium (Ti), gold (Au), silver (Ag), copper (Cu), or an alloy thereof. However, the present disclosure is not limited thereto.

The second electrode 125 is disposed on the second semiconductor layer 123. The second electrode 125 may be disposed on an upper surface (e.g., top surface) of the second semiconductor layer 123. The second electrode 125 is an electrode for electrically connecting the high-potential power line VDD and the second semiconductor layer 123. In this case, the second semiconductor layer 123 may be a semiconductor layer doped with p-type impurities, and the second electrode 125 may be an anode. The second electrode 125 may be made of an electrically conductive material, for example, a transparent conductive material such as indium tin oxide (ITO) or indium zinc oxide (IZO) or an opaque conductive material such as titanium (Ti), gold (Au), silver (Ag), copper (Cu), or an alloy thereof. However, the present disclosure is not limited thereto.

Next, the encapsulation film 126 is disposed to surround the first semiconductor layer 121, the red light-emitting layer 122R, the second semiconductor layer 123, the first electrode 124, and the second electrode 125. The encapsulation film 126 may be made of an insulating material and protect the first semiconductor layer 121, the red light-emitting layer 122R, and the second semiconductor layer 123. Further, a contact hole, through which the first electrode 124 and the second electrode 125 are exposed, may be formed in the encapsulation film 126, such that the first connection electrode CE1 and the first electrode 124 may be electrically connected, and a second connection electrode CE2 and the second electrode 125 may be electrically connected.

In addition, a part of a side surface of the first semiconductor layer 121 may be exposed from the encapsulation film 126. The light-emitting element 120 manufactured on a wafer may be separated from the wafer and transferred to the display panel PN. However, a part of the encapsulation film 126 may be torn during a process of separating the light-emitting element 120 from the wafer. For example, a part of the encapsulation film 126 adjacent to a lower edge of the first semiconductor layer 121 of the light-emitting element 120 may be torn during the process of separating the light-emitting element 120 from the wafer, such that a part of a lower side surface of the first semiconductor layer 121 may be exposed to the outside. Even though the lower portion of the light-emitting element 120 is exposed from the encapsulation film 126, the first connection electrode CE1 and the second connection electrode CE2 are formed after a second planarization layer 115b, which covers the side surface of the first semiconductor layer 121, is formed, thereby reducing a short circuit defect.

Next, the second planarization layer 115b is disposed on the first bonding layer AD1 and the red light-emitting element 120R. The second planarization layer 115b may be disposed to cover the red light-emitting elements 120R of the first sub-pixel SP1 and the reserve sub-pixel SPA. The second planarization layer 115b may be configured as a single layer or multilayer and made of a photoresist or an acrylic-based organic material, for example. However, the present disclosure is not limited thereto.

The second planarization layer 115b may be disposed to cover the red light-emitting element 120R and fix and protect the red light-emitting element 120R. The second planarization layer 115b may cover a torn portion of the encapsulation film 126 that protects the side surface of the first semiconductor layer 121 of the red light-emitting element 120R. Therefore, the second planarization layer 115b covers a lower portion of the first semiconductor layer 121 from which the encapsulation film 126 is torn, thereby suppressing a contact defect and a short circuit defect of the connection electrode and the first semiconductor layer 121.

In addition, a contact hole, through which the first electrode 124 and the second electrode 125 of the red light-emitting element 120R are exposed, may be formed in the second planarization layer 115b. The first electrode 124 and the second electrode 125 of the red light-emitting element 120R may be exposed from the second planarization layer 115b. However, the second planarization layer 115b is partially disposed in an area between the first electrode 124 and the second electrode 125, thereby reducing a short circuit defect.

The first connection electrode CE1, which is connected to the first electrode 124 of the light-emitting element 120, and the second connection electrode CE2, which is connected to the second electrode 125 of the light-emitting element 120, are disposed in each of the plurality of sub-pixels SP and the reserve sub-pixel SPA. The first connection electrode CE1, which is disposed in each of the plurality of sub-pixels SP, may electrically connect the driving transistor DT and the first electrode 124 of the light-emitting element 120. The first connection electrode CE1, which is disposed in the reserve sub-pixel SPA, may electrically connect the repair line WRL and the first electrode 124 of the light-emitting element 120. The second connection electrode CE2, which is disposed in each of the plurality of sub-pixels SP and the reserve sub-pixel SPA, may electrically connect the high-potential power line VDD and the second electrode 125 of the light-emitting element 120. The first connection electrode CE1 and the second connection electrode CE2 may be made of a transparent conductive material such as indium tin oxide (ITO) or indium zinc oxide (IZO). However, the present disclosure is not limited thereto.

In this case, the plurality of light-emitting elements 120 are respectively disposed on different layers, such that the first connection electrode CE1 and the second connection electrode CE2 may also be configured as a plurality of electrodes disposed on different layers. For example, the first connection electrode CE1 includes a first-first connection electrode CE1a connected to the first electrode 124 of the red light-emitting element 120R, a first-second connection electrode CE1b connected to the first electrode 124 of the green light-emitting element 120G, and a first-third connection electrode CE1c connected to the first electrode 124 of the blue light-emitting element 120B. The second connection electrode CE2 may include a second-first connection electrode CE2a connected to the second electrode 125 of the red light-emitting element 120R, a second-second connection electrode CE2b connected to the second electrode 125 of the green light-emitting element 120G, and a second-third connection electrode CE2c connected to the second electrode 125 of the blue light-emitting element 120B.

First, the first-first connection electrode CE1a and the second-first connection electrode CE2a are provided on the second planarization layer 115b and disposed in the first sub-pixel SP1 and the reserve sub-pixel SPA. The first-first connection electrode CE1a may be electrically connected to the first electrode 124 of the red light-emitting element 120R through a contact hole formed in the second planarization layer 115b. The second-first connection electrode CE2a may be electrically connected to the second electrode 125 of the red light-emitting element 120R through a contact hole formed in the second planarization layer 115b.

The first-first connection electrode CE1a, which is disposed in the first sub-pixel SP1, may be electrically connected to the first reflective electrode RE1 through contact holes formed in the second planarization layer 115b, the first bonding layer AD1, and the third passivation layer 114c. Therefore, in the first sub-pixel SP1, the first electrode 124 and the first reflective electrode RE1 of the red light-emitting element 120R, the auxiliary electrode AE, and the driving source electrode DSE may be electrically connected to one another by the first-first connection electrode CE1a.

The first-first connection electrode CE1a, which is disposed in the reserve sub-pixel SPA, may be connected to a first repair line WRL1 among the plurality of repair lines WRL. The first-first connection electrode CE1a and the first repair line WRL1 may be disposed on the same layer, made of the same material, and integrated with each other. Therefore, in the reserve sub-pixel SPA, the first repair line WRL1 and the first electrode 124 of the red light-emitting element 120R may be electrically connected by the first-first connection electrode CE1a.

The repair line WRL is a line that electrically connects the light-emitting element 120 of the reserve sub-pixel SPA to the driving transistor DT of another sub-pixel SP when a defect occurs. A more detailed description thereof will be described below.

The second-first connection electrode CE2a, which is disposed in the first sub-pixel SP1, may be electrically connected to the second reflective electrode RE2 or the high-potential power line VDD through contact holes formed in the second planarization layer 115b, the first bonding layer AD1, and the third passivation layer 114c. Therefore, in the first sub-pixel SP1, the high-potential power line VDD and the second electrode 125 of the red light-emitting element 120R may be electrically connected to each other by the second-first connection electrode CE2a.

The second-first connection electrode CE2a, which is disposed in the reserve sub-pixel SPA, may be electrically connected to the second reflective electrode RE2 or the high-potential power line VDD through contact holes formed in the second planarization layer 115b, the first bonding layer AD1, and the third passivation layer 114c. Therefore, in the reserve sub-pixel SPA, the high-potential power line VDD and the second electrode 125 of the red light-emitting element 120R may be electrically connected to each other by the second-first connection electrode CE2a. In this case, in case that the repair process is not performed, the first electrode 124 of the red light-emitting element 120R may be in a floating state without being connected to the driving transistor DT. Therefore, even though the second electrode 125 of the red light-emitting element 120R of the reserve sub-pixel SPA is electrically connected to the high-potential power line VDD, it is possible to suppress a situation in which the red light-emitting element 120R of the reserve sub-pixel SPA abnormally emits light.

The second bonding layer AD2 is disposed on the second planarization layer 115b, the first-first connection electrode CE1a, and the second-first connection electrode CE2a. The second bonding layer AD2 may be formed on the front surface of the substrate 110 and fix the green light-emitting element 120G disposed on the second bonding layer AD2. The second bonding layer AD2 may be made of a photocurable bonding material that may be cured by light. For example, the second bonding layer AD2 may be made of any one of adhesive polymer, epoxy resist, UV resin, a polyimide-based material, an acrylate-based material, a urethane-based material, and polydimethylsiloxane (PDMS). However, the present disclosure is not limited thereto.

The green light-emitting element 120G is disposed on the second bonding layer AD2 and provided in each of the second sub-pixel SP2 and the reserve sub-pixel SPA. In this case, the green light-emitting element 120G disposed in the reserve sub-pixel SPA may overlap the area in which the red light-emitting element 120R is disposed in the reserve sub-pixel SPA. For example, the green light-emitting element 120G and the red light-emitting element 120R may be disposed to overlap each other in the reserve sub-pixel SPA.

The green light-emitting element 120G includes the first semiconductor layer 121, a green light-emitting layer 122G, the second semiconductor layer 123, the first electrode 124, the second electrode 125, and the encapsulation film 126. The green light-emitting element 120G has substantially the same structure as the red light-emitting element 120R, except that the green light-emitting element 120G includes the green light-emitting layer 122G. For example, the first semiconductor layer 121, the green light-emitting layer 122G, and the second semiconductor layer 123 of the green light-emitting element 120G are sequentially disposed on the second bonding layer AD2, and the first electrode 124 and the second electrode 125 may be respectively disposed above the first semiconductor layer 121 and the second semiconductor layer 123. Further, the encapsulation film 126 may be formed to surround the first semiconductor layer 121, the green light-emitting layer 122G, the second semiconductor layer 123, the first electrode 124, and the second electrode 125 of the green light-emitting element 120G.

Next, a third planarization layer 115c is disposed on the second bonding layer AD2 and the green light-emitting element 120G. The third planarization layer 115c may be disposed to cover the green light-emitting elements 120G of the second sub-pixel SP2 and the reserve sub-pixel SPA. The third planarization layer 115c may be configured as a single layer or multilayer and made of a photoresist or an acrylic-based organic material, for example. However, the present disclosure is not limited thereto.

The first-second connection electrode CE1b and the second-second connection electrode CE2b are disposed on the third planarization layer 115c and disposed in the second sub-pixel SP2 and the reserve sub-pixel SPA. The first-second connection electrode CE1b may be electrically connected to the first electrode 124 of the green light-emitting element 120G through a contact hole formed in the third planarization layer 115c. The second-second connection electrode CE2b may be electrically connected to the second electrode 125 of the green light-emitting element 120G through a contact hole formed in the third planarization layer 115c.

The first-second connection electrode CE1b, which is disposed in the second sub-pixel SP2, may be electrically connected to the first reflective electrode RE1 through contact holes formed in the third planarization layer 115c, the second bonding layer AD2, the second planarization layer 115b, the first bonding layer AD1, and the third passivation layer 114c. Therefore, in the second sub-pixel SP2, the first electrode 124 and the first reflective electrode RE1 of the green light-emitting element 120G, the auxiliary electrode AE, and the driving source electrode DSE may be electrically connected to one another by the first-second connection electrode CE1b.

The first-second connection electrode CE1b, which is disposed in the reserve sub-pixel SPA, may be connected to a second repair line WRL2 among the plurality of repair lines WRL. The first-second connection electrode CE1b and the second repair line WRL2 may be disposed on the same layer, made of the same material, and integrated with each other. Therefore, in the reserve sub-pixel SPA, the second repair line WRL2 and the first electrode 124 of the green light-emitting element 120G may be electrically connected by the first-second connection electrode CE1b.

The second-second connection electrode CE2b, which is disposed in the second sub-pixel SP2, may be electrically connected to the second reflective electrode RE2 or the high-potential power line VDD through contact holes formed in the third planarization layer 115c, the second bonding layer AD2, the second planarization layer 115b, the first bonding layer AD1, and the third passivation layer 114c. Therefore, in the second sub-pixel SP2, the high-potential power line VDD and the second electrode 125 of the green light-emitting element 120G may be electrically connected to each other by the second-second connection electrode CE2b.

The second-second connection electrode CE2b, which is disposed in the reserve sub-pixel SPA, may also be electrically connected to the second reflective electrode RE2 or the high-potential power line VDD through contact holes formed in the third planarization layer 115c, the second bonding layer AD2, the second planarization layer 115b, the first bonding layer AD1, and the third passivation layer 114c. Therefore, in the reserve sub-pixel SPA, the high-potential power line VDD and the second electrode 125 of the green light-emitting element 120G may be electrically connected to each other by the second-second connection electrode CE2b.

Next, the third bonding layer AD3 is disposed on the third planarization layer 115c, the first-second connection electrode CE1b, and the second-second connection electrode CE2b. The third bonding layer AD3 may be formed on the front surface of the substrate 110 and fix the blue light-emitting element 120B disposed on the third bonding layer AD3. The third bonding layer AD3 may be made of a photocurable bonding material that may be cured by light. For example, the third bonding layer AD3 may be made of any one of adhesive polymer, epoxy resist, UV resin, a polyimide-based material, an acrylate-based material, a urethane-based material, and polydimethylsiloxane (PDMS). However, the present disclosure is not limited thereto.

The blue light-emitting element 120B is disposed on the third bonding layer AD3 and provided in each of the third sub-pixel SP3 and the reserve sub-pixel SPA. The blue light-emitting element 120B of the reserve sub-pixel SPA may overlap the green light-emitting element 120G and the red light-emitting element 120R. The red light-emitting element 120R, the green light-emitting element 120G, and the blue light-emitting element 120B, which are disposed in the reserve sub-pixel SPA, may at least partially overlap one another.

The blue light-emitting element 120B includes the first semiconductor layer 121, a blue light-emitting layer 122B, the second semiconductor layer 123, the first electrode 124, the second electrode 125, and the encapsulation film 126. The blue light-emitting element 120B has substantially the same structure as the red light-emitting element 120R and the green light-emitting element 120G, except that the blue light-emitting element 120B includes the blue light-emitting layer 122B. For example, the first semiconductor layer 121, the blue light-emitting layer 122B, and the second semiconductor layer 123 of the blue light-emitting element 120B may be sequentially disposed on the third bonding layer AD3, and the first electrode 124 and the second electrode 125 may be respectively disposed above the first semiconductor layer 121 and the second semiconductor layer 123. Further, the encapsulation film 126 may be formed to surround the first semiconductor layer 121, the blue light-emitting layer 122B, the second semiconductor layer 123, the first electrode 124, and the second electrode 125 of the blue light-emitting element 120B.

Next, a fourth planarization layer 115d is disposed on the third bonding layer AD3 and the blue light-emitting element 120B. The fourth planarization layer 115d may be disposed to cover the blue light-emitting elements 120B of the third sub-pixel SP3 and the reserve sub-pixel SPA. The fourth planarization layer 115d may be configured as a single layer or multilayer and made of a photoresist or an acrylic-based organic material, for example. However, the present disclosure is not limited thereto.

The first-third connection electrode CE1c and the second-third connection electrode CE2c are disposed on the fourth planarization layer 115d and disposed in the third sub-pixel SP3 and the reserve sub-pixel SPA. The first-third connection electrode CE1c may be electrically connected to the first electrode 124 of the blue light-emitting element 120B through a contact hole formed in the fourth planarization layer 115d. The second-third connection electrode CE2c may be electrically connected to the second electrode 125 of the blue light-emitting element 120B through a contact hole formed in the fourth planarization layer 115d.

The first-third connection electrode CE1c, which is disposed in the third sub-pixel SP3, may be electrically connected to the first reflective electrode RE1 through contact holes formed in the fourth planarization layer 115d, the third bonding layer AD3, the third planarization layer 115c, the second bonding layer AD2, the second planarization layer 115b, the first bonding layer AD1, and the third passivation layer 114c. Therefore, in the third sub-pixel SP3, the first electrode 124 and the first reflective electrode RE1 of the blue light-emitting element 120B, the auxiliary electrode AE, and the driving source electrode DSE may be electrically connected to one another by the first-third connection electrode CE1c.

The first-third connection electrode CE1c disposed in the reserve sub-pixel SPA may be connected to a third repair line WRL3 among the plurality of repair lines WRL. The first-third connection electrode CE1c and the third repair line WRL3 may be disposed on the same layer, made of the same material, and integrated with each other. Therefore, in the reserve sub-pixel SPA, the third repair line WRL3 and the first electrode 124 of the blue light-emitting element 120B may be electrically connected by the first-third connection electrode CE1c.

The second-third connection electrode CE2c, which is disposed in the third sub-pixel SP3, may be electrically connected to the second reflective electrode RE2 or the high-potential power line VDD through contact holes formed in the fourth planarization layer 115d, the third bonding layer AD3, the third planarization layer 115c, the second bonding layer AD2, the second planarization layer 115b, the first bonding layer AD1, and the third passivation layer 114c. Therefore, in the third sub-pixel SP3, the high-potential power line VDD and the second electrode 125 of the blue light-emitting element 120B may be electrically connected to each other by the second-third connection electrode CE2c.

The second-third connection electrode CE2c, which is disposed in the reserve sub-pixel SPA, may also be electrically connected to the second reflective electrode RE2 or the high-potential power line VDD through the contact holes formed in the fourth planarization layer 115d, the third bonding layer AD3, the third planarization layer 115c, the second bonding layer AD2, the second planarization layer 115b, the first bonding layer AD1, and the third passivation layer 114c. Therefore, in the reserve sub-pixel SPA, the high-potential power line VDD and the second electrode 125 of the blue light-emitting element 120B may be electrically connected to each other by the second-third connection electrode CE2c.

In this case, with reference to FIG. 8, the second-third connection electrode CE2c, the second-second connection electrode CE2b, and the second-first connection electrode CE2a of the reserve sub-pixel SPA may be connected to the high-potential power line VDD through the same contact hole. Therefore, the second-third connection electrode CE2c may adjoin the second-second connection electrode CE2b, and the second-second connection electrode CE2b may adjoin the second-first connection electrode CE2a. Therefore, in the reserve sub-pixel SPA, the second-third connection electrode CE2c, the second-second connection electrode CE2b, the second-first connection electrode CE2a, the second electrode 125 of the red light-emitting element 120R, the second electrode 125 of the green light-emitting element 120G, and the second electrode 125 of the blue light-emitting element 120B may be electrically connected to one another.

Next, in the pixel area UPA, a bank BB is disposed on the fourth planarization layer 115d, the first-third connection electrode CE1c, and the second-third connection electrode CE2c. The bank BB may be disposed to be spaced apart, at a predetermined interval, from areas in which the plurality of light-emitting elements 120 is disposed. The bank BB may be disposed between the plurality of sub-pixels SP and disposed on a boundary between the first sub-pixel SP1 and the reserve sub-pixel SPA, and the bank BB may cover a part of the first connection electrode CE1 and a part of the second connection electrode CE2. The bank BB may be disposed to be spaced apart from the transmissive area TA. The bank BB may be made of an opaque material, for example, black particle or black resin to reduce a color mixture between the plurality of sub-pixels SP and the reserve sub-pixel SPA. However, the present disclosure is not limited thereto.

In addition, although not illustrated in the drawings, a protective layer may be further disposed on the bank BB. The protective layer is a layer for protecting components disposed below the protective layer. The protective layer may be configured as a single layer or multilayer made of benzocyclobutene, light transmissive epoxy, a photoresist, an acrylic-based organic material, or an inorganic material silicon oxide (SiOx) or silicon nitride (SiNx), for example. However, the present disclosure is not limited thereto.

Next, the plurality of repair lines WRL is disposed between the reserve sub-pixel SPA and the plurality of sub-pixels SP. The plurality of repair lines WRL are lines for repairing the defective sub-pixels SP by electrically connecting the light-emitting elements 120 of the reserve sub-pixels SPA to the driving transistors DT of the defective sub-pixels SP when defects occur on the light-emitting elements 120 of some of the sub-pixels SP. When a defect occurs on the light-emitting element 120 of any one of the plurality of sub-pixels SP, the repair line WRL may be used to connect the light-emitting element 120 of the reserve sub-pixel SPA to the pixel circuit of the defective sub-pixel SP to operate the light-emitting element 120 of the reserve sub-pixel SPA instead of the defective light-emitting element 120.

The plurality of repair lines WRL may be disposed on an outer peripheral portion of the pixel area UPA and disposed adjacent to the transmissive area TA. Therefore, the plurality of repair lines WRL may be made of a transparent conductive material such as indium tin oxide (ITO) or indium zinc oxide (IZO), thereby minimizing or at least reducing a decrease in transmittance rate.

The plurality of repair lines WRL includes the first repair line WRL1, the second repair line WRL2, and the third repair line WRL3. The first repair line WRL1, the second repair line WRL2, and the third repair line WRL3 may at least partially overlap one another. The first repair line WRL1, the second repair line WRL2, and the third repair line WRL3 may be disposed on different layers.

First, the first repair line WRL1 is provided on the second planarization layer 115b and disposed between the reserve sub-pixel SPA and the first sub-pixel SP1. The first repair line WRL1 is a line for electrically connecting the red light-emitting element 120R of the reserve sub-pixel SPA and the pixel circuit of the first sub-pixel SP1 when a defect occurs on the red light-emitting element 120R of the first sub-pixel SP1. One end of the first repair line WRL1 may be connected to the first-first connection electrode CE1a of the reserve sub-pixel SPA, and the other end of the first repair line WRL1 may overlap the first reflective electrode RE1 of the first sub-pixel SP1. The other end of the first repair line WRL1 may be disposed to overlap the first reflective electrode RE1 of the first sub-pixel SP1 and disposed to be spaced apart from the first-first connection electrode CE1a of the first sub-pixel SP1. When a defect occurs on the red light-emitting element 120R of the first sub-pixel SP1, a welding process of irradiating the other end of the first repair line WRL1 with laser beams may be performed to electrically connect the first repair line WRL1 and the first reflective electrode RE1. Therefore, after the welding process, the red light-emitting element 120R of the reserve sub-pixel SPA may be operated by being electrically connected to the driving transistor DT of the first sub-pixel SP1 through the first repair line WRL1.

The second repair line WRL2 is provided on the third planarization layer 115c and disposed between the reserve sub-pixel SPA and the second sub-pixel SP2. The second repair line WRL2 is a line for electrically connecting the green light-emitting element 120G of the reserve sub-pixel SPA and the pixel circuit of the second sub-pixel SP2 when a defect occurs on the green light-emitting element 120G of the second sub-pixel SP2. One end of the second repair line WRL2 may be connected to the first-second connection electrode CE1b of the reserve sub-pixel SPA, and the other end of the second repair line WRL2 may overlap the first reflective electrode RE1 of the second sub-pixel SP2. The other end of the second repair line WRL2 may be disposed to overlap the first reflective electrode RE1 of the second sub-pixel SP2 and disposed to be spaced apart from the first-second connection electrode CE1b of the second sub-pixel SP2. When a defect occurs on the green light-emitting element 120G of the second sub-pixel SP2, a welding process of irradiating the other end of the second repair line WRL2 with laser beams may be performed to electrically connect the second repair line WRL2 and the first reflective electrode RE1. Therefore, after the welding process, the green light-emitting element 120G of the reserve sub-pixel SPA may be operated by being electrically connected to the driving transistor DT of the second sub-pixel SP2 through the second repair line WRL2.

The third repair line WRL3 is provided on the fourth planarization layer 115d and disposed between the reserve sub-pixel SPA and the third sub-pixel SP3. The third repair line WRL3 is a line for electrically connecting the blue light-emitting element 120B of the reserve sub-pixel SPA and the pixel circuit of the third sub-pixel SP3 when a defect occurs on the blue light-emitting element 120B of the third sub-pixel SP3. One end of the third repair line WRL3 may be connected to the first-third connection electrode CE1c of the reserve sub-pixel SPA, and the other end of the third repair line WRL3 may overlap the first reflective electrode RE1 of the third sub-pixel SP3. The other end of the third repair line WRL3 may be disposed to overlap the first reflective electrode RE1 of the third sub-pixel SP3 and disposed to be spaced apart from the first-third connection electrode CE1c of the third sub-pixel SP3. When a defect occurs on the blue light-emitting element 120B of the third sub-pixel SP3, a welding process of irradiating the other end of the third repair line WRL3 with laser beams may be performed to electrically connect the third repair line WRL3 and the first reflective electrode RE1. Therefore, after the welding process, the blue light-emitting element 120B of the reserve sub-pixel SPA may be operated by being electrically connected to the driving transistor DT of the third sub-pixel SP3 through the third repair line WRL3.

The first repair line WRL1, the second repair line WRL2, and the third repair line WRL3 may at least partially overlap one another. Because the first repair line WRL1, the second repair line WRL2, and the third repair line WRL3 are disposed on different layers, the first repair line WRL1, the second repair line WRL2, and the third repair line WRL3 do not interfere with one another even though the first repair line WRL1, the second repair line WRL2, and the third repair line WRL3 are disposed in the same area. For example, a part of the first repair line WRL1 and a part of the second repair line WRL2 may overlap each other, and a part of the second repair line WRL2 may overlap the third repair line WRL3.

However, among the plurality of repair lines WRL, only one repair line WRL may be disposed in the welding area WA of each of the plurality of sub-pixels SP. For example, only the other end of the first repair line WRL1 may be disposed in the welding area WA of the first sub-pixel SP1. If the first repair line WRL1 and the second repair line WRL2 are disposed together in the welding area WA of the first sub-pixel SP1, the first repair line WRL1, the second repair line WRL2, and the first reflective electrode RE1 are connected together during the welding process, which may cause a defect in which the green light-emitting element 120G is connected to the driving transistor DT of the first sub-pixel SP1. Therefore, only one repair line WRL may be disposed in the welding area WA.

In addition, the area in which the first reflective electrode RE1 and the other of each of the plurality of repair lines WRL overlap may also be defined as the welding area WA to be irradiated with laser beams during the repair process.

Further, the first connection electrode CE1 of each of the plurality of sub-pixels SP is not disposed in the welding area WA. If the first connection electrode CE1 is disposed even in the welding area WA, the repair line WRL and the first connection electrode CE1 are connected to each other, and the light-emitting element 120 of the reserve sub-pixel SPA or the sub-pixel SP may operate abnormally. Therefore, the first-first connection electrode CE1a of the first sub-pixel SP1, the first-second connection electrode CE1b of the second sub-pixel SP2, and the first-third connection electrode CE1c of the third sub-pixel SP3 may be disposed to be spaced apart from the welding area WA.

Next, with reference to FIGS. 4, 9, and 10, when a defect occurs on the light-emitting element 120 of any one of the plurality of sub-pixels SP, the repair process may be performed by separating the pixel circuit and the defective light-emitting element 120 and connecting the light-emitting element 120 of the reserve sub-pixel SPA to the pixel circuit of the sub-pixel SP on which the defective light-emitting element 120 is disposed.

First, the defective light-emitting element 120 and the pixel circuit may be separated. If the pixel circuit and the defective light-emitting element 120 are not electrically separated, a bright spot defect may occur in which the defective light-emitting element 120 operates abnormally. For example, the defective light-emitting element 120 continuously emits light regardless of images, which may cause a problem in which a bright spot is recognized. Therefore, the pixel circuit and the defective light-emitting element 120 may be separated so that the drive current is not supplied from the pixel circuit to the defective light-emitting element 120.

A drive current transmission route between the defective light-emitting element 120 and the pixel circuit may be eliminated by destroying the connection portion between the defective light-emitting element 120 and the driving source electrode DSE of the driving transistor DT. The light-emitting element 120 and the driving transistor DT of each of the plurality of sub-pixels SP may be electrically connected to each other through the auxiliary electrode AE, the first reflective electrode RE1, and the first connection electrode CE1. Further, any one of the connection portions between the auxiliary electrode AE, the first reflective electrode RE1, and the first connection electrode CE1 may be destroyed by being irradiated with laser beams. For example, the first connection electrode CE1 and the first reflective electrode RE1 may be electrically separated by irradiating the area in which the contact hole through which the first connection electrode CE1 and the first reflective electrode RE1 are connected is disposed with laser beams. Therefore, the route through which the drive current is supplied between the defective light-emitting element 120 and the driving transistor DT may be blocked, which may suppress a bright spot defect in which the defective light-emitting element 120 consistently emits light. However, another portion of the connection portions between the driving transistor DT and the defective light-emitting element 120 may be irradiated with laser beams, and the present disclosure is not limited thereto. It is to be noted that, although FIGS. 4 to 8 show a detailed arrangement and layer structure of the display device, but it is only provided by way of example, and the present disclosure is not limited thereto. For example, the layer structure of the display device may be variously changed, and one or more of the interlayer insulation layers or the planarization layers may be omitted when necessary.

Next, with reference to FIGS. 9 and 10, the repair line WRL may be electrically connected to the first reflective electrode RE1 of the sub-pixel SP, in which the defective light-emitting element 120 is disposed, by irradiating the other end of the repair line WRL connected to the light-emitting element 120 of the same type as the light-emitting element 120 of the defective sub-pixel SP with laser beams. For example, the repair line WRL and the first reflective electrode RE1 may be electrically connected by irradiating the welding area WA of the other end of the repair line WRL with laser beams. The welding process of electrically connecting the repair line WRL and the first reflective electrode RE1 may be performed to electrically connect one of the light-emitting elements 120 of the reserve sub-pixel SPA to the pixel circuit of the sub-pixel SP, e.g., the driving transistor DT. Therefore, instead of the defective light-emitting element 120, the light-emitting element 120 of the reserve sub-pixel SPA may be operated by being connected to the pixel circuit of another sub-pixel SP, such that images may be normally displayed.

For example, in case that the red light-emitting element 120R of the first sub-pixel SP1 is defective, the contact portion between the first-first connection electrode CE1a of the first sub-pixel SP1 and the first reflective electrode RE1 may be destroyed, which may suppress a bright spot defect of the defective red light-emitting element 120R. Further, with reference to FIGS. 9 and 10, the first repair line WRL1 and the first reflective electrode RE1 of the first sub-pixel SP1 may be electrically connected by irradiating the welding area WA, in which the first repair line WRL1 and the first reflective electrode RE1 of the first sub-pixel SP1 overlap each other, with laser beams. Therefore, the red light-emitting element 120R of the reserve sub-pixel SPA may be electrically connected between the high-potential power line VDD and the driving transistor DT of the first sub-pixel SP1 and supplied with the drive current. Therefore, instead of the defective red light-emitting element 120R of the first sub-pixel SP1, the red light-emitting element 120R of the reserve sub-pixel SPA may display images, and the reserve sub-pixel SPA may serve as the first sub-pixel SP1.

For example, in case that the green light-emitting element 120G of the second sub-pixel SP2 is defective, the contact portion between the first-second connection electrode CE1b of the second sub-pixel SP2 and the first reflective electrode RE1 may be destroyed, which may suppress a bright spot defect of the defective green light-emitting element 120G. Further, the second repair line WRL2 and the first reflective electrode RE1 of the second sub-pixel SP2 may be electrically connected by irradiating the welding area WA, in which the second repair line WRL2 and the first reflective electrode RE1 of the second sub-pixel SP2 overlap each other, with laser beams. Therefore, the green light-emitting element 120G of the reserve sub-pixel SPA may be electrically connected between the high-potential power line VDD and the driving transistor DT of the second sub-pixel SP2 and supplied with the drive current. Therefore, instead of the defective green light-emitting element 120G of the second sub-pixel SP2, the green light-emitting element 120G of the reserve sub-pixel SPA may display images, and the reserve sub-pixel SPA may serve as the second sub-pixel SP2.

Lastly, in case that the blue light-emitting element 120B of the third sub-pixel SP3 is defective, the contact portion between the first-third connection electrode CE1c of the third sub-pixel SP3 and the first reflective electrode RE1 may be destroyed, which may suppress a bright spot defect of the defective blue light-emitting element 120B. Further, the third repair line WRL3 and the first reflective electrode RE1 of the third sub-pixel SP3 may be electrically connected by irradiating the welding area WA, in which the third repair line WRL3 and the first reflective electrode RE1 of the third sub-pixel SP3 overlap each other, with laser beams. Therefore, the blue light-emitting element 120B of the reserve sub-pixel SPA may be electrically connected between the high-potential power line VDD and the driving transistor DT of the third sub-pixel SP3 and supplied with the drive current. Therefore, instead of the defective blue light-emitting element 120B of the third sub-pixel SP3, the blue light-emitting element 120B of the reserve sub-pixel SPA may display images, and the reserve sub-pixel SPA may serve as the third sub-pixel SP3.

In this case, the red light-emitting element 120R, the green light-emitting element 120G, and the blue light-emitting element 120B, which are disposed in the reserve sub-pixel SPA, and the repair line WRL, which is connected to the red light-emitting element 120R, the green light-emitting element 120G, and the blue light-emitting element 120B, may be disposed on different layers and separated from one another. Therefore, even though two or more sub-pixels SP are defective among the first sub-pixel SP1, the second sub-pixel SP2, and the third sub-pixel SP3, one reserve sub-pixel SPA may be used to repair the two or more sub-pixels SP. For example, when the first sub-pixel SP1 and the second sub-pixel SP2 are defective, both the red light-emitting element 120R and the green light-emitting element 120G of the reserve sub-pixel SPA may be electrically connected to the driving transistors DT of the first sub-pixel SP1 and the second sub-pixel SP2, such that the reserve sub-pixel SPA may serve as both the first sub-pixel SP1 and the second sub-pixel SP2.

In addition, in the reserve sub-pixel SPA, the plurality of light-emitting elements 120 may be disposed to at least partially overlap one another. However, the light-emitting elements 120, which are positioned at the upper side among the plurality of light-emitting elements 120, may be configured to be substantially transparent, which may minimize or at least reduce a degree to which the light-emitting elements 120 hinder the propagation of light emitted from the other light-emitting elements 120.

For example, in case that the red light-emitting element 120R, which is disposed at the lowermost side among the plurality of light-emitting elements 120, emits light, the first electrodes 124 and the second electrodes 125 of the green light-emitting element 120G and the blue light-emitting element 120B disposed over the red light-emitting element 120R may be made of a transparent conductive material, such that the light emitted from the red light-emitting element 120R may propagate normally. For example, in the reserve sub-pixel SPA, the green light-emitting element 120G and the blue light-emitting element 120B disposed on the red light-emitting element 120R may include the transparent first electrodes 124 and the transparent second electrodes 125 so that the light emitted from the red light-emitting element 120R propagates to the outside of the display device 100. Likewise, in case that the green light-emitting element 120G of the reserve sub-pixel SPA emits light, the blue light-emitting element 120B on the green light-emitting element 120G may include the transparent first electrode 124 and the transparent second electrode 125 so that the light emitted from the green light-emitting element 120G may easily propagate to the outside of the display device 100.

Further, at least any one of the first electrode 124 and the second electrode 125 of the red light-emitting element 120R, which is disposed at the lowermost side among the plurality of light-emitting elements 120 of the reserve sub-pixel SPA, may be made of an opaque conductive material. However, because the red light-emitting element 120R having the opaque electrode is disposed below the green light-emitting element 120G and the blue light-emitting element 120B in the reserve sub-pixel SPA, the red light-emitting element 120R may not hinder the propagation of the light emitted from the green light-emitting element 120G and the blue light-emitting element 120B. However, the present disclosure is not limited thereto, and the first electrode 124 and the second electrode 125 of the red light-emitting element 120R may also be made of a transparent conductive material.

Therefore, according to the display device 100 according to one or more embodiments of the present disclosure, when the light-emitting element 120 disposed in each of the plurality of sub-pixels SP is defective, the reserve sub-pixel SPA may eliminate the defect. All the red light-emitting element 120R, the green light-emitting element 120G, and the blue light-emitting element 120B are disposed in the reserve sub-pixel SPA. Further, in case that any one of the light-emitting elements 120 disposed in the first sub-pixel SP1, the second sub-pixel SP2, and the third sub-pixel SP3 is defective, the light-emitting element 120 of the reserve sub-pixel SPA may be electrically connected to the pixel circuit of the sub-pixel SP including the defective light-emitting element 120, such that the light-emitting element 120 of the reserve sub-pixel SPA may operate instead of the defective light-emitting element 120. For example, in case that the red light-emitting element 120R of the first sub-pixel SP1 is defective, the red light-emitting element 120R of the reserve sub-pixel SPA and the driving transistor DT of the first sub-pixel SP1 may be electrically connected, such that the red light-emitting element 120R of the reserve sub-pixel SPA may operate.

In this case, the light-emitting element 120 of the reserve sub-pixel SPA and the pixel circuits of the plurality of sub-pixels SP may be selectively connected by using the plurality of repair lines WRL. For example, one end of each of the plurality of repair lines WRL may be electrically connected to the first electrode 124 of each of the plurality of light-emitting elements 120 of the reserve sub-pixel SPA, and the other end of each of the plurality of repair lines WRL may overlap the first reflective electrode RE1 of each of the plurality of sub-pixels SP. At the initial time, the other end of the repair line WRL and the first reflective electrode RE1 may be in an insulated state with an insulation layer interposed therebetween. Further, in case that the sub-pixel SP including the defective light-emitting element 120 is detected, the insulation layer may be opened by irradiating the welding area WA, in which the first reflective electrode RE1 and the other end of the repair line WRL overlap, with laser beams, such that the first reflective electrode RE1 and the repair line WRL may be electrically connected. Therefore, the light-emitting element 120 of the reserve sub-pixel SPA may be electrically connected to the driving transistor DT of the sub-pixel SP including the defective light-emitting element 120 through the repair line WRL and the first reflective electrode RE1.

In addition, in the related art, a plurality of light-emitting elements is connected to one pixel circuit to prepare for a defect of a sub-pixel, and even though one light-emitting element is defective, the sub-pixel is operated by using the remaining light-emitting elements. However, because the plurality of light-emitting elements is connected to one pixel circuit in parallel, a density of the drive current to be supplied to the light-emitting elements decreases, and luminous efficiency of the light-emitting elements deteriorates.

Therefore, according to the display device 100 according to one or more embodiments of the present disclosure, only one light-emitting element 120 is connected to one pixel circuit, which may improve the density of the drive current to be supplied to the light-emitting element 120. For example, the driving transistor DT of the pixel circuit of the first sub-pixel SP1 may be connected only to one red light-emitting element 120R and supply the high-density drive current. Further, even though a defect occurs on the light-emitting element 120 disposed in each of the sub-pixels SP, the light-emitting element 120 disposed in the reserve sub-pixel SPA may be used to repair the light-emitting element 120, which may minimize or at least reduce the deterioration in display quality of the display device 100.

In addition, according to the display device 100 according to one or more embodiments of the present disclosure, the plurality of light-emitting elements 120 formed in the reserve sub-pixel SPA may be stacked in the vertical direction, which may reduce the area occupied by the reserve sub-pixel SPA. For example, in the reserve sub-pixel SPA, the red light-emitting element 120R may be disposed on the first bonding layer AD1, the green light-emitting element 120G may be disposed over the red light-emitting element 120R, the blue light-emitting element 120B may be disposed over the green light-emitting element 120G, and the red light-emitting element 120R, the green light-emitting element 120G, and the blue light-emitting element 120B may at least partially overlap one another. In this case, the area for disposing the red light-emitting element 120R, the area for disposing the green light-emitting element 120G, and the area for disposing the blue light-emitting element 120B may be formed on different planes. If the red light-emitting element 120R, the green light-emitting element 120G, and the blue light-emitting element 120B are disposed on the same layer, the area of the reserve sub-pixel SPA may increase to ensure the area for disposing the red light-emitting element 120R, the area for disposing the green light-emitting element 120G, and the area for disposing the blue light-emitting element 120B. Therefore, in the display device 100 according to one or more embodiments of the present disclosure, the red light-emitting element 120R, the green light-emitting element 120G, and the blue light-emitting element 120B may be stacked in the reserve sub-pixel SPA, which may reduce the area occupied by the reserve sub-pixel SPA and increase the area of the transmissive area TA of the display device 100 to the extent that the area of the reserve sub-pixel SPA is reduced.

In addition, one pixel PX does not include a plurality of extra sub-pixels SP for repairing the plurality of sub-pixels SP, but one pixel PX includes only one reserve sub-pixel SPA, which may reduce the area of the pixel area UPA. Therefore, more pixel areas UPA may be formed while maintaining the transmittance rate at the same level as the related art, which may implement the high-resolution display device 100.

In the display device 100 according to one or more embodiments of the present disclosure, the electrode of the light-emitting element 120, which is disposed at the upper side among the plurality of light-emitting elements 120 vertically stacked in the reserve sub-pixel SPA, may be made of a transparent conductive material so as not to inhibit the light, which is emitted from the light-emitting element 120 positioned at the lower side, from propagating. In order to reduce the area of the reserve sub-pixel SPA, the red light-emitting element 120R, the green light-emitting element 120G, and the blue light-emitting element 120B may be disposed while being vertically stacked and overlapping one another. In this case, when the electrodes of the green light-emitting element 120G and the blue light-emitting element 120B disposed on the red light-emitting element 120R are made of an opaque conductive material, the efficiency in propagating light emitted from the red light-emitting element 120R disposed at the lower side may deteriorate or be lowered. Therefore, the electrodes of the green light-emitting element 120G and the blue light-emitting element 120B positioned on the red light-emitting element 120R may be made of a transparent conductive material, which may improve the light propagation efficiency of the reserve sub-pixel SPA.

The embodiments of the present disclosure can also be described as follows:

According to one or more embodiments of the present disclosure, a display device includes a substrate having a plurality of pixel areas, a plurality of pixels disposed in the plurality of pixel areas, and each including a first sub-pixel, a second sub-pixel, a third sub-pixel, and a reserve sub-pixel, first light-emitting elements respectively disposed in the first sub-pixel and the reserve sub-pixel, second light-emitting elements respectively disposed in the second sub-pixel and the reserve sub-pixel, and third light-emitting elements respectively disposed in the third sub-pixel and the reserve sub-pixel, the first light-emitting element, the second light-emitting element, and the third light-emitting element are disposed on different layers in the reserve sub-pixel.

The first light-emitting element, the second light-emitting element, and the third light-emitting element at least may partially overlap one another in the reserve sub-pixel.

The first light-emitting element of the first sub-pixel may be disposed on the same layer as the first light-emitting element of the reserve sub-pixel, the second light-emitting element of the second sub-pixel may be disposed on the same layer as the second light-emitting element of the reserve sub-pixel, and the third light-emitting element of the third sub-pixel may be disposed on the same layer as the third light-emitting element of the reserve sub-pixel.

The plurality of repair lines may include a first repair line having one end connected to a first electrode of the first light-emitting element of the reserve sub-pixel, a second repair line having one end connected to a first electrode of the second light-emitting element of the reserve sub-pixel, and a third repair line having one end connected to a first electrode of the third light-emitting element of the reserve sub-pixel, and the first repair line, the second repair line, and the third repair line may be disposed on different layers.

The display device may further include driving transistors respectively disposed in the first sub-pixel, the second sub-pixel, and the third sub-pixel, first reflective electrodes respectively provided in the first sub-pixel, the second sub-pixel, and the third sub-pixel, disposed on the driving transistors, and each configured to electrically connect the driving transistor and the first electrode of each of the first light-emitting element, the second light-emitting element, and the third light-emitting element, and second reflective electrodes respectively provided in the first sub-pixel, the second sub-pixel, and the third sub-pixel, disposed on the driving transistors, and electrically connected to the second electrode of each of the first light-emitting element, the second light-emitting element, and the third light-emitting element.

The display device may further include a first planarization layer disposed between the driving transistor and the first reflective electrode and between the driving transistor and the second reflective electrode, a first bonding layer disposed on the first reflective electrode and the second reflective electrode and having an upper surface to which the first light-emitting element is attached, a second planarization layer disposed on the first light-emitting element and the first bonding layer, a second bonding layer disposed on the second planarization layer and having an upper surface to which the second light-emitting element is attached, a third planarization layer disposed on the second light-emitting element and the second bonding layer, a third bonding layer disposed on the third planarization layer and having an upper surface to which the third light-emitting element is attached, and a fourth planarization layer disposed on the third light-emitting element and the third bonding layer.

The first repair line may be disposed between the second planarization layer and the second bonding layer, the second repair line may be disposed between the third planarization layer and the third bonding layer, and the third repair line may be disposed on the fourth planarization layer.

The display device may further include first-first connection electrodes provided in the first sub-pixel and the reserve sub-pixel, each disposed between the second planarization layer and the second bonding layer, and each electrically connected to the first electrode of the first light-emitting element, first-second connection electrodes provided in the second sub-pixel and the reserve sub-pixel, each disposed between the third planarization layer and the third bonding layer, and each electrically connected to the first electrode of the second light-emitting element, and first-third connection electrodes provided in the third sub-pixel and the reserve sub-pixel, each disposed on the fourth planarization layer, and each electrically connected to the first electrode of the third light-emitting element, the first-first connection electrode and the first repair line may be disposed to be spaced apart from each other, the first-second connection electrode and the second repair line may be disposed to be spaced apart from each other, and the first-third connection electrode and the third repair line may be disposed to be spaced apart from each other.

The first-first connection electrode in the first sub-pixel may be electrically connected to the first reflective electrode through contact holes formed in the second planarization layer and the first bonding layer, the first-second connection electrode in the second sub-pixel may be electrically connected to the first reflective electrode through contact holes formed in the third planarization layer, the second bonding layer, the second planarization layer, and the first bonding layer, and the first-third connection electrode in the third sub-pixel may be electrically connected to the first reflective electrode through contact holes formed in the fourth planarization layer, the third bonding layer, the third planarization layer, the second bonding layer, the second planarization layer, and the first bonding layer.

The display device may further include second-first connection electrodes provided in the first sub-pixel and the reserve sub-pixel, each disposed between the second planarization layer and the second bonding layer, and each electrically connected to the second reflective electrode and the second electrode of the first light-emitting element, second-second connection electrodes provided in the second sub-pixel and the reserve sub-pixel, each disposed between the third planarization layer and the third bonding layer, and each electrically connected to the second reflective electrode and the second electrode of the second light-emitting element, and second-third connection electrodes provided in the third sub-pixel and the reserve sub-pixel, each disposed on the fourth planarization layer, and each electrically connected to the second reflective electrode and the second electrode of the third light-emitting element.

A contact hole, through which the second-first connection electrode and the second reflective electrode are in contact with each other, a contact hole, through which the second-second connection electrode and the second reflective electrode are in contact with each other, and a contact hole, through which the second-third connection electrode and the second reflective electrode are in contact with each other, may overlap one another, and the second-first connection electrode, the second-second connection electrode, and the second-third connection electrode may adjoin one another.

The first electrode and the second electrode of the third light-emitting element may be made of a transparent conductive material, and the first electrode and the second electrode of the second light-emitting element may be made of a transparent conductive material.

The first electrode and the second electrode of the first light-emitting element may be at least partially made of an opaque conductive material.

The other end of the first repair line may overlap the first reflective electrode of the first sub-pixel, the other end of the second repair line may overlap the first reflective electrode of the second sub-pixel, and the other end of the third repair line may overlap the first reflective electrode of the third sub-pixel.

In some of the plurality of pixels, the other end of each of the plurality of repair lines and the first reflective electrode may be disposed to be spaced apart from each other with an insulation layer interposed therebetween.

In some of the remaining pixels among the plurality of pixels, the insulation layer may be opened, and the other end of one of the first repair line, the second repair line, and the third repair line and the first reflective electrode may be connected to each other.

Although the embodiments of the present disclosure have been described in detail with reference to the accompanying drawings, the present disclosure is not limited thereto and may be embodied in many different forms without departing from the technical concept of the present disclosure. Therefore, the embodiments of the present disclosure are provided for illustrative purposes only but not intended to limit the technical concept of the present disclosure. The scope of the technical concept of the present disclosure is not limited thereto. Therefore, it should be understood that the above-described embodiments are illustrative in all aspects and do not limit the present disclosure. All the technical concepts in the equivalent scope of the present disclosure should be construed as falling within the scope of the present disclosure.

What is claimed is:

1. A display device, comprising:
a substrate having a plurality of pixel areas;
a plurality of pixels in the plurality of pixel areas, each of the plurality of pixels including a first sub-pixel, a second sub-pixel, a third sub-pixel, and a reserve sub-pixel;
a first plurality of light-emitting elements in the first sub-pixel and the reserve sub-pixel;
a second plurality of light-emitting elements in the second sub-pixel and the reserve sub-pixel; and
a third plurality of light-emitting elements in the third sub-pixel and the reserve sub-pixel,
wherein a first light-emitting element of the first plurality of light-emitting elements, a second light-emitting element of the second plurality of light-emitting elements, and a third light-emitting element of the third plurality of light-emitting elements are on different layers in the reserve sub-pixel.

2. The display device of claim 1, wherein the plurality of pixel areas are spaced apart from one another, and a transmissive area is between the plurality of pixel areas.

3. The display device of claim 1, wherein the first plurality of light-emitting elements emit red light, the second plurality of light-emitting elements emit green light, and the third plurality of light-emitting elements emit blue light.

4. The display device of claim 1, wherein the first light-emitting element, the second light-emitting element, and the third light-emitting element at least partially overlap one another in the reserve sub-pixel.

5. The display device of claim 1, wherein a light-emitting element of the first plurality of light-emitting elements of the first sub-pixel is on a same layer as another light-emitting element of the first plurality of light-emitting elements of the reserve sub-pixel, a light-emitting element of the second plurality of light-emitting elements of the second sub-pixel is on a same layer as another light-emitting element of the second plurality of light-emitting elements of the reserve sub-pixel, and a light-emitting element of the third plurality of light-emitting elements of the third sub-pixel is on a same layer as another light-emitting element of the third plurality of light-emitting elements of the reserve sub-pixel.

6. The display device of claim 1, further comprising a plurality of repair lines connected to the reserve sub-pixel,
wherein the plurality of repair lines comprises:
a first repair line having one end connected to a first electrode of a light-emitting element of the first plurality of light-emitting elements of the reserve sub-pixel;
a second repair line having one end connected to a first electrode of a light-emitting element of the second plurality of light-emitting elements of the reserve sub-pixel; and
a third repair line having one end connected to a first electrode of a light-emitting element of the third plurality of light-emitting elements of the reserve sub-pixel, and
wherein the first repair line, the second repair line, and the third repair line are on different layers.

7. The display device of claim 6, wherein the first repair line, the second repair line, and the third repair line at least partially overlap one another.

8. The display device of claim 6, further comprising:
a plurality of driving transistors in the first sub-pixel, the second sub-pixel, and the third sub-pixel;
a first plurality of reflective electrodes in the first sub-pixel, the second sub-pixel, and the third sub-pixel, wherein the first plurality of reflective electrodes are on the plurality of driving transistors, and each of the first plurality of reflective electrodes is configured to electrically connect a driving transistor of the plurality of driving transistors and the first electrode of corresponding one of the light-emitting element of the first plurality of light-emitting elements, the light-emitting element of the second plurality of light-emitting elements, and the light-emitting element of the third plurality of light-emitting elements; and
a second plurality of reflective electrodes in the first sub-pixel, the second sub-pixel, and the third sub-pixel, wherein the second plurality of reflective electrodes are on the plurality of driving transistors, and the second plurality of reflective electrodes are electrically connected to a second electrode of the light-emitting element of the first plurality of light emitting elements, a second electrode of the light-emitting element of the second plurality of light-emitting elements, and a second electrode of the light-emitting element of the third plurality of light-emitting elements.

9. The display device of claim 8, further comprising: a data line and a low-potential power line that are connected to and overlapping with the plurality of pixel areas,
wherein the low-potential power line is between the data line and the driving transistor, and the low-potential power line at least covering a driving gate electrode of the driving transistor.

10. The display device of claim 8, further comprising:
a first planarization layer between the driving transistor and a first reflective electrode of the first plurality of reflective electrodes, and the first planarization layer is further between the driving transistor and a second reflective electrode of the second plurality of reflective electrodes;
a first bonding layer on the first reflective electrode and the second reflective electrode, the first light-emitting element attached to an upper surface of the first bonding layer;
a second planarization layer on the first light-emitting element and the first bonding layer;
a second bonding layer on the second planarization layer, the second light-emitting element attached to an upper surface of the second bonding layer;
a third planarization layer on the second light-emitting element and the second bonding layer;
a third bonding layer on the third planarization layer, the third light-emitting element attached to an upper surface of the third bonding layer; and
a fourth planarization layer on the third light-emitting element and the third bonding layer.

11. The display device of claim 10, wherein the first repair line is between the second planarization layer and the second bonding layer, the second repair line is between the third planarization layer and the third bonding layer, and the third repair line is on the fourth planarization layer.

12. The display device of claim 11, further comprising:
a plurality of first-first connection electrodes in the first sub-pixel and the reserve sub-pixel, each of the plurality of first-first connection electrodes between the second planarization layer and the second bonding layer, and each of the plurality of first-first connection electrodes electrically connected to the first electrode of the light-emitting element of the first plurality of light-emitting elements;
a plurality of first-second connection electrodes in the second sub-pixel and the reserve sub-pixel, each of the plurality of first-second connection electrodes between the third planarization layer and the third bonding layer, and each of the plurality of first-second connection electrodes electrically connected to the first electrode of the light-emitting element of the second plurality of light-emitting elements; and
a plurality of first-third connection electrodes in the third sub-pixel and the reserve sub-pixel, each of the plurality of first-third connection electrodes on the fourth planarization layer, and each of the plurality of first-third connection electrodes electrically connected to the first electrode of the light-emitting element of the third plurality of light-emitting elements,
wherein a first-first connection electrode of the plurality of first-first connection electrodes and the first repair line are spaced apart from each other, a first-second connection electrode of the plurality of first-second connection electrodes and the second repair line are spaced apart from each other, and a first-third connection electrode of the plurality of first-third connection electrodes and the third repair line are spaced apart from each other.

13. The display device of claim 12, wherein:
the first-first connection electrode is electrically connected to the first reflective electrode through a first plurality of contact holes in the second planarization layer and the first bonding layer,
the first-second connection electrode is electrically connected to the first reflective electrode through a second plurality of contact holes in the third planarization layer, the second bonding layer, the second planarization layer, and the first bonding layer, and
the first-third connection electrode is electrically connected to the first reflective electrode through a third plurality of contact holes in the fourth planarization layer, the third bonding layer, the third planarization layer, the second bonding layer, the second planarization layer, and the first bonding layer.

14. The display device of claim 11, further comprising:
a plurality of second-first connection electrodes in the first sub-pixel and the reserve sub-pixel, each of the plurality of second-first connection electrodes between the second planarization layer and the second bonding layer, and each of the plurality of second-first connection electrodes electrically connected to the second reflective electrode and the second electrode of the light-emitting element of the first plurality of light-emitting elements;
a plurality of second-second connection electrodes in the second sub-pixel and the reserve sub-pixel, each of the plurality of second-second connection electrodes between the third planarization layer and the third bonding layer, and each of the plurality of second-second connection electrodes electrically connected to the second reflective electrode and the second electrode of the light-emitting element of the second plurality of light-emitting elements; and
a plurality of second-third connection electrodes in the third sub-pixel and the reserve sub-pixel, each of the plurality of second-third connection electrodes on the fourth planarization layer, and each of the plurality of second-third connection electrodes electrically connected to the second reflective electrode and the second electrode of the light-emitting element of the third plurality of light-emitting elements.

15. The display device of claim 14, wherein a first contact hole, a second contact hole, and a third contact hole overlap one another,
a second-first connection electrode of the plurality of second-first connection electrodes and the second reflective electrode are in contact with each other through the first contact hole,
a second-second connection electrode of the plurality of second-second connection electrodes and the second reflective electrode are in contact with each other through the second contact hole,
a second-third connection electrode of the plurality of second-third connection electrodes and the second reflective electrode are in contact with each other through the third contact hole, and
the second-first connection electrode, the second-second connection electrode, and the second-third connection electrode adjoin one another.

16. The display device of claim 10, wherein the first electrode and the second electrode of the light-emitting element of the third plurality of light-emitting elements include a first transparent conductive material, and the first electrode and the second electrode of the light-emitting element of the second plurality of light-emitting elements include a second transparent conductive material.

17. The display device of claim 16, wherein the first electrode and the second electrode of the light-emitting element of the first plurality of light-emitting elements at least partially include an opaque conductive material.

18. The display device of claim 8, wherein another end of the first repair line overlaps a first reflective electrode of the first plurality of reflective electrodes of the first sub-pixel, another end of the second repair line overlaps a first reflective electrode of the first plurality of reflective electrodes of the second sub-pixel, and another end of the third repair line overlaps a first reflective electrode of the first plurality of reflective electrodes of the third sub-pixel.

19. The display device of claim 18, wherein, in a subset of the plurality of pixels, an end of each of the plurality of repair lines and the first reflective electrode of a respective one of the first sub-pixel, the second sub-pixel, and the third sub-pixel are spaced apart from each other with an insulation layer.

20. The display device of claim 19, wherein, in a portion of the plurality of pixels that are not in the subset, an insulation layer is opened, and the other end of one of the first repair line, the second repair line, and the third repair line is connected to the first reflective electrode of one of the first sub-pixel, the second sub-pixel, and the third sub-pixel.
